(19) United States
(12) Patent Application Publication
(10) Pub. No.: US 2026/0172015 A1
(43) Pub. Date: Jun. 18, 2026

(54) DYNAMIC MICRO-ARCHITECTURAL CIRCUIT CONFIGURATION

(71) Applicant: Intel Corporation, Santa Clara, CA (US)

(72) Inventors: Julien SEBOT, Portland, OR (US); Ahmed Mohamed YOUSSEF, Tigard, OR (US); Manjith KUMAR, Portland, OR (US); Viral THAKER, Portland, OR (US); Robbie TOMASZEWSKI, Cedar Park, TX (US)

(21) Appl. No.: 18/982,767

(22) Filed: Dec. 16, 2024

(51) Int. Cl. H03K 5/24; G06F 13/20

(52) U.S. Cl. CPC H03K 5/24; G06F 13/20

(57) ABSTRACT

Disclosed are circuits for dynamically configuring configurable micro-architectural circuits based on associated operating point indicators.

### TECHNICAL FIELD

Embodiments relate to the field of semiconductors and more specifically, to the field of micro-architectural circuits.

### BRIEF DESCRIPTION OF THE DRAWINGS

The disclosure may best be understood by referring to the following description and accompanying drawings that are used to illustrate embodiments of the invention. In the drawings:

FIG. 1 is a block diagram showing dynamically configurable micro-architectural circuit units in accordance with some embodiments.

FIG. 2A is a block diagram of a dynamic Uarch configuration system in accordance with some embodiments.

FIG. 2B is a table showing an exemplary uarch configuration table in accordance with some embodiments.

FIG. 3 is a flow diagram showing a routine for controlling uarch configuration based on configuration state in accordance with some embodiments.

FIG. 4 illustrates an example computing system.

FIG. 5 illustrates a block diagram of an example processor and/or System on a Chip (SoC) that may have one or more cores and an integrated memory controller.

FIG. 6 is a block diagram illustrating a computing system 600 configured to implement one or more aspects of the examples described herein.

FIG. 7A illustrates examples of a parallel processor.

FIG. 7B illustrates examples of a block diagram of a partition unit.

FIG. 7C illustrates examples of a block diagram of a processing cluster within a parallel processing unit.

FIG. 7D illustrates examples of a graphics multiprocessor in which the graphics multiprocessor couples with the pipeline manager of the processing cluster.

FIGS. 8A-8C illustrate additional graphics multiprocessors, according to examples.

FIG. 9 shows a parallel compute system 900, according to some examples.

FIGS. 10A-10B illustrate a hybrid logical/physical view of a disaggregated parallel processor, according to examples described herein.

FIG. 11(A) is a block diagram illustrating both an example in-order pipeline and an example register renaming, out-of-order issue/execution pipeline according to examples.

FIG. 11(B) is a block diagram illustrating both an example in-order architecture core and an example register renaming, out-of-order issue/execution architecture core to be included in a processor according to examples.

FIG. 12 illustrates examples of execution unit(s) circuitry, such as execution unit(s) circuitry.

FIG. 13 is a block diagram of a register architecture according to some examples.

FIG. 14 illustrates examples of an instruction format.

FIGS. 15A-15B illustrate thread execution logic including an array of processing elements employed in a graphics processor core according to examples described herein.

FIG. 16 illustrates an additional execution unit, according to an example.

FIG. 17 is a block diagram illustrating a graphics processor instruction format 1700 according to some examples.

FIG. 18 is a block diagram of another example of a graphics processor.

FIG. 19A is a block diagram illustrating a graphics processor command format according to some examples.

FIG. 19B is a block diagram illustrating a graphics processor command sequence according to an example.

FIG. 20 is a block diagram illustrating the use of a software instruction converter to convert binary instructions in a source ISA to binary instructions in a target ISA according to examples.

FIG. 21 is a block diagram illustrating an IP core development system 2100 that may be used to manufacture an integrated circuit to perform operations according to some examples.

### DETAILED DESCRIPTION

Micro-architectural functional circuits, such as floating point units, pre-fetch units, and speculative execution units, to mention just a few, may be characterized based on their power to performance ratio (PPR). For example, PPR may be defined as the ratio of the percentage of Cdyn (dynamic capacitance, a proxy for power consumption) change to the percentage of IPC (instructions per cycle) change at a given voltage. Traditionally, with many processor design specifications, micro-architectural (uarch) functional units have had to have PPRs of 1 or less in order to be included into a processor core design. This means that a uarch unit, or unit feature, that increases Cdyn by one percent is acceptable, provided it leads to a one percent or more improvement in IPC.

Realistically, however, there are many different possible uarch circuit designs, or uarch feature flavors, that may have value in certain scenarios even though their PPRs are higher. Of course, this level of acceptable PPRs is affected by the use case for a given product. For example, uarch designs that have higher PPRs (e.g., 6 or higher) may be acceptable in form factors where power constraints are less important such as with desktop or HPC (high performance computing) processors, while they may be unacceptable in mobile or even in some server platforms. Even with form factors where power constraints are less stringent, some uarch designs could have value, but traditional approaches of adding only features which are beneficial over the widest possible frequency range causes them to be left out of products. Often times, they may be omitted from higher end offerings because they cannot be justified for inclusion into lower power platform versions of a processor family.

Accordingly, in some embodiments, approaches are provided to facilitate the inclusion of a wider array of uarch circuit units and;/or features regardless of whether their PPR is sufficiently low. In some embodiments, configurable uarch circuits may be dynamically configured (e.g., enabled/disabled or increased/decreased) based on a current operating point. This allows the addition of features that have higher PPRs because they can be limited to operate at frequencies where they have relevant value and disabled, or reduced, for lower operating points where their PPR inefficiencies are more problematic. Uarch P-states (uP-states) may be used to dynamically reconfigure hardware to enable performance friendly (but power hungry) features at higher processor operating points, and to disable, or limit, these uarch circuits at lower performance states when power savings are more important. It also allows for feature aggressiveness to be tuned (e.g. front-end speculation, data prefetcher etc.) according to runtime performance requirements. This also can allow for a reduction in validation by minimizing the number of combinations of features and operating points that can occur simultaneously.

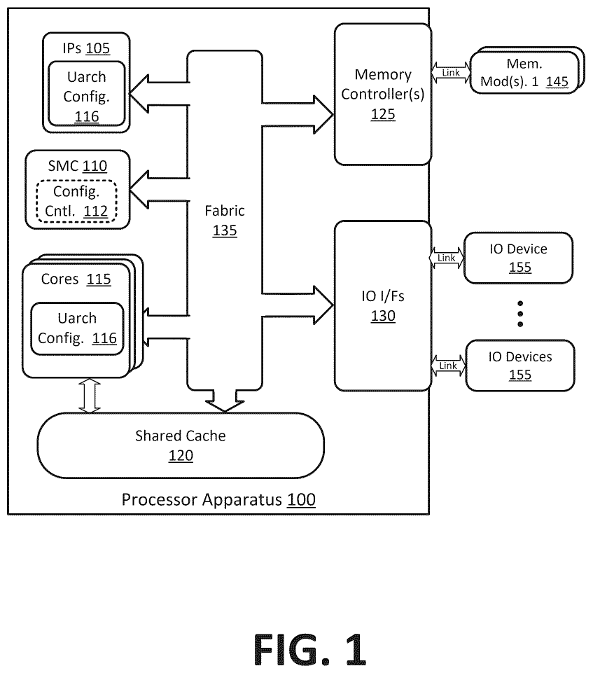

FIG. 1 is a block diagram showing dynamically configurable micro-architectural circuit units in accordance with some embodiments. The processor 100 includes IP (intellectual property) circuits 105, a system management controller (SMC) 110, processing cores 115, shared cash circuitry 120, a memory controller 125, IO interface circuits 130, and system fabric 135, all coupled together as shown. Also included are memory modules 145 coupled to the memory controller(s) 125 through memory channels. Similarly, IO devices 155 coupled to the I/O interface circuits 150 through IO interface channels are also included.

The processor apparatus 200 comprises at least one hardware circuit configured to execute instructions (e.g., in processor cores 115) contained in program code. The hardware circuit may be implemented with one or more integrated circuits. Examples of processor types that may be implemented in processor 100 include, but are not limited to, a central processing unit (CPU), an array processor, a vector processor, a digital signal processor (DSP), a field-programmable gate array (FPGA), an application specific integrated circuit (ASIC), a graphics processing unit (GPU), an artificial intelligence processing unit (AIPU), and so forth. It should be appreciated that the processor 100 may be implemented in various different manners. For example, it may be implemented on a single die, multiple dies (dielets, chiplets), one or more dies in a common package, or one or more dies in multiple packages. Along these lines, some of the depicted blocks may be located separately on different dies or together on two or more different dies.

The IP circuits 105 are circuits that perform a particular function. An IP circuit (or IP) may be a unit of logic, circuit, cell, or chip layout that is reusable. A few examples of IP circuits include processor cores, memories, caches, floating point processors, memory controllers, bus controllers, graphics processors, transceivers, network interface controllers, and display controllers. One or more portions of a larger IP can themselves be designated as IP circuits. For example, an instruction execution unit and cache controller may be IP for a processor IP. In some embodiments, one or more IP blocks may include a uarch configuration circuit 116 as will be described below to dynamically control uarch circuit configurations in the one or more IP blocks.

The SMC 110 includes one or more microcontrollers, state machines and/or other logic circuits for controlling various aspects of the processor 200. For example, it may manage functions such as security, boot configuration, and power and performance including utilized and allocated power along with thermal management. The SMC may also be referred to as a P-unit, a power management unit (PMU), a power control unit (PCU), a system management unit (SMU) and the like and may include multiple SMCs, PMUs, die management controllers, etc.

In some embodiments, the SMC 110 includes a uarch unit configuration controller to control configuration and/or configuration operating parameters for dynamic uarch unit configuration circuits as discussed below. The configuration controller 112 may be implemented with the SMC running code (e.g., firmware), or it may be implemented wholly or partially with dedicated control logic circuitry such as a micro-controller or finite state machine (FSM).

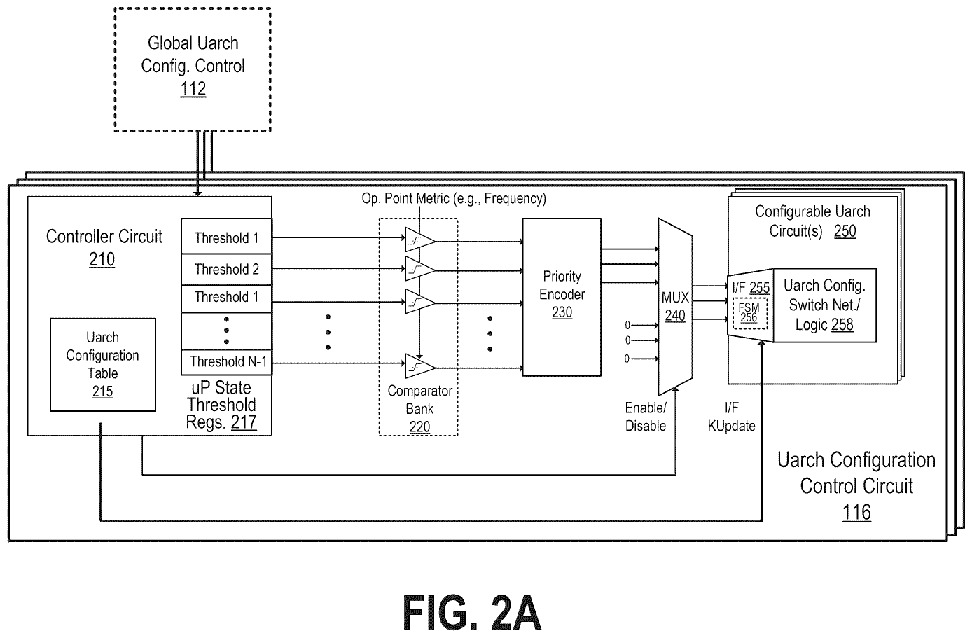

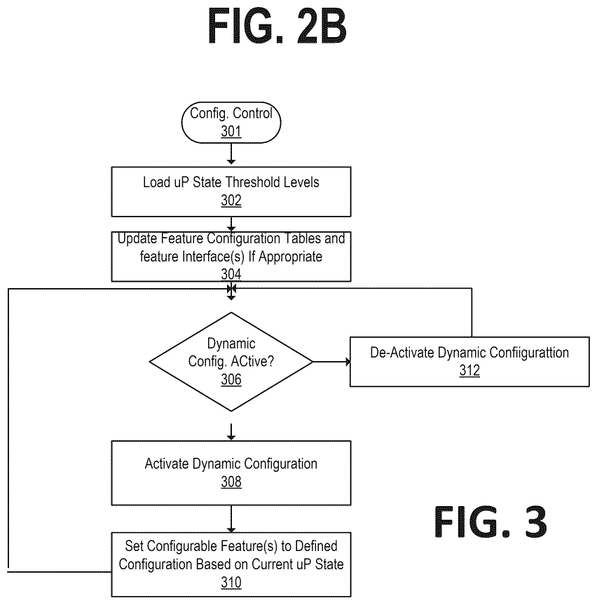

The processing cores 115 comprise cores for executing code in accordance with desired functionality for the processor 100. They may comprise any suitable combination of core types such as compute (e.g., CPU) cores, graphics cores, parallel processing cores, vector processing cores, and the like, and may be implemented with differently sized instances and/or by using the same or different instruction set architectures. Specific implementations will depend on functionality, as well as power and performance objectives. One or more of the cores 115 may include a uarch configuration circuit 116 for controlling uarch unit configurations for uarch units, or features, included within a core. An example of a uarch configuration circuit 116 is described below with respect to FIG. 2A.

The shared cache 120 includes one or more levels of cache memory, typically random access memory (RAM) that is used by the other blocks in the processor including the processor cores 115. Some or all of it may be part of an overall memory system that also includes the memory modules 145. The IO devices 155 and their associated IO interfaces 130 are coupled with the Processor 100 to provide additional functionality and/or better performance capabilities. For example, they may include IO interface devices such as PCIe (Peripheral chip Interconnect express), USB (Universal Serial Bus) and/or CXL (Compute Express Link) interfaces for peripheral user interface devices, displays, accelerators, and the like.

The fabric 135 is a communications network of interconnected nodes to couple to one another the various different blocks of the processor 100. In some embodiments, it facilitates high-speed data transfer and communication, which allows for the creation of unified computing systems where the different components can work together. For convenience, a single overall fabric is shown, but fabric 135 may comprise multiple different fabrics and interconnection structures such as mesh and ring networks, as well as busses and point-to-point connections. In some embodiments, it may include separate different fabrics, e.g., a main data fabric for transferring data between the blocks and a control fabric for setting parameters, reading operational states, managing operating modes, communicating telemetry, and the like.

The memory controller(s) 125 is coupled to the memory modules 145. The memory modules are typically made up of DRAM memory chips, and each module may include a power delivery circuit and a memory module controller to interface between the raw memory and the memory controller 125. The memory may be implemented using any suitable type such as DDR double data rate), LPDDR (Low Power DDR), and the like. Accordingly, the channels that make up the channel groups operate in conformance with whatever memory type is being implemented.

FIG. 2A is a block diagram of a dynamic Uarch configuration system in accordance with some embodiments. The system includes one or more uarch configuration circuits 116 for configuring uarch circuits in one or more different partitions of a processor. Each uarch configuration circuit 116 may be used to control micro-architectural processing circuit configurations for an associated partition. As used herein, the term, “partition” refers to a group of functional processing circuitry such as a core, a core portion, a core cluster, an IP (intellectual property) block, or a functional circuit block that has at least one associated operating point indicator such as a clock frequency that corresponds to an operating point (e.g., power/performance state) for the partition. A uarch configuration circuit 116 may operate autonomously and/or in cooperation with an optional global uarch configuration control circuit 112 that may be used, for example, to program and oversee operations of the one or more uarch configuration circuits 116. In some embodiments, a global uarch configuration control circuit 112 may be implemented in an SMC such as with SMC 110 from FIG. 1. Likewise, uarch configuration circuits 116 may be implemented for configuring uarch circuits in different partitions such as in different cores 115 or IP blocks 105 as described with regard to FIG. 1.

With the depicted embodiment, the uarch configuration control circuit(s) 116 include controller circuit 210, comparator bank 220, priority encoder circuit 230, multiplexer (Mux) 240 and configurable uarch circuits 250, coupled together as shown. The controller circuit 210 includes a uarch configuration table 215, a plurality of uarch uP-state registers 217, and control circuitry (not shown) such as a micro-controller and/or state machines to control updating and/or loading of the data stored in table 215 and threshold registers 217. For example, the table and registers may be implemented with writeable memory that may be populated at boot, for example, by controller circuit 210, e.g., off of fused configuration and threshold data or from updates provided to the processor such as through an SMC by way of a BIOS (basic input/output system) update or other suitable scheme. The configuration table 215 includes uP-state definitions for the various different configurable uarch circuits 250 based on a current operational uP-state. The threshold levels stored in threshold registers 217 store specific operating points that define the different uP-states. For example, with an associated clock frequency used as an operating point identifier, each threshold level might define an upper or lower frequency boundary for a given uP-state.

As a simple example, assume there are to be three different uP-states with two upper-boundary thresholds to define the three states. A first lowest performance level uP-state might range from a lowest frequency to 1 GHz; a second mid-level performance uP-state might range from 1 GHz to 3 GHz; while the highest performance state ranges from 3 GHz. to a highest possible frequency level. With this example, the two thresholds loaded into the threshold registers would be 1 GHz and 3 GHz. The table 215 identifies a particular configuration for each uarch circuit based on which of the three uP-states it is currently in.

The comparator bank 220 includes a plurality of comparators to compare a received operating point identifier (e.g., clock frequency, core clock frequency ratio, voltage, or other) against a threshold as received from threshold registers 215. The operating point identifier may come from any suitable source such as an SMC, a local power management circuit or a local signal corresponding to a current operating point, e.g., a local clock reference frequency or ratio.

The comparators output a plurality of digital values (‘0 or ‘1) corresponding to the received operating point identifier and its particular threshold level. For example, using the above three uP-state example, there could be two comparators, one for the 1 GHz threshold and one for the 3 GHz. threshold. If the received operating point was, for example, 2.4 GHz., then the 1 GHz comparator could assert, while the 3 GHz. comparator could de-assert.

The outputs from the comparator bank 220 are provided to the priority encoder circuit 230. The priority encoder translates the comparator outputs into a configuration state value corresponding to the lowest asserted comparator or the lowest comparator if no comparator asserts. (For this example, lowest corresponds to lowest performance, e.g., lowest frequency. However, the threshold registers are labeled such that Threshold 1 is actually the highest threshold, highest performance state, while threshold N is the lowest threshold. This is consistent with ACPI nomenclature where, for example, C0 is a highest package performance state.) So, sticking with the above example, the priority encoder would generate an output indicating that the current uP-state (also referred to as configuration state) is the mid-level state, between 1 GHz. and 3 GHz. (Note that with the depicted figure, an 8 uP-state example is used. Accordingly, there are three lines shown coming out of the priority encoder to identify one of eight different configuration states. If the comparator threshold scheme is used as just described, there could then be seven utilized comparators for the comparator bank 220.)

With this eight configuration state example, the mux 240 receives two sets of three signals. The first set includes the configuration state signals from the priority encoder, while the second set includes three inputs that are all de-asserted. The latter corresponds to a null, or disabled, mode that is one of the 8 configuration states, although it is separately provided for efficient, fast disabling of dynamic configuration state operation. The first (enabled) configuration state signals or the second, disabled signals, may be selected through an Enable/Disable signal from the controller circuit 210.

The output lines from the mux 240 are provided to the configurable uarch circuit(s) 250, which include an interface (I/F) circuit 255 and micro-architectural (uarch) configuration switch network/logic circuit (also referred to as uarch switch logic) 258. The interface 255 decodes the uP-state indicator signal and controls the uarch switch logic to provide a suitable combination of control signals in an appropriate sequence, if necessary, to place the configurable uarch circuit in the proper configuration based on the decoded uP-state. The uarch switch logic may include any suitable combination of switches, gates, latches, control registers and other memory elements to control a configurable uarch circuit to efficiently transition the uarch circuit into a proper configuration. For example, if pipeline slots are to be reduced or speculative execution is to be made less aggressive, executing contexts may have to be properly re-queued, buffered, etc. in order to transition in an expedited, reliable manner.

There are numerous possible configurable uarch circuits that may be controlled as described based on a current configuration state for a given partition. For example, a dynamically adjustable speculation circuit may be employed. With large depth speculation architectures (e.g., 4K or higher re-order buffer and large widths, e.g., 28-wide decode), there is a potential for a large amount of waste in allocated uops (micro operations) in cases where clears occur. This can be even more problematic with traces having high branch misprediction rates or long branch resolution latencies. But, with dynamic speculation limiting (DSL), the front end is able to dynamically control the amount of speculation based, for example, on monitored runtime program behavior, e.g., wastage and branch confidence information. In addition, with a dynamically configurable speculation circuit, Cdyn may be reduced for high wastage traces without giving up too much performance. The high performance configurations may be maintained for low wastage traces with speculation being limited based on the running operating point, which indirectly indicates whether the power management scheme (or policy) is currently concerned more with power or performance. The operating point indicator (e.g., core frequency) may be used to pick a “dynamic speculation configuration that specifies an amount of speculation aggressiveness corresponding to a current power and performance policy without having to implement complicated power management algorithms for the different possible configurations. The least limiting configurations would yield the lowest Cdyn savings, while the most limiting would yield the highest Cdyn savings. Note that configurable dynamic speculation circuits may operate with any suitable speculative architectural method such as with eager execution and/or branch prediction.

Other types of configurable uarch circuits may be implemented including but not limited to the number of active pipelines, degree of pre-fetch aggressiveness, as well as so-called pulse-glide schemes. Pulse/glide schemes involve controlling the number of utilized time slots (queues) for thread execution to consolidate workloads into a smaller number of enabled slots, enabling more aggressive power reduction, or alternatively, using a higher number of queues, to yield potentially higher performance but typically at the cost of lower power savings opportunities. Other types of configurable uarch circuits include arithmetic logic unit circuits, floating point unit circuits, load/store unit circuits, branch prediction unit circuits, instruction fetch unit circuits, register file circuits, cache circuits, control unit circuits, memory management unit circuits, and various additional execution unit circuits.

In some embodiments, the interface 255 includes a finite state machine (FSM) for generating the configuration control signals with appropriate sequencing and timing for controlling the uarch switch logic. Note that in the depicted embodiment, there is shown an interface for each configurable uarch circuit 250 in a partition, but in some embodiments, fewer, including a single, interface(s) may be used for multiple uarch configuration circuits in a partition.

FIG. 2B is a table showing an exemplary uarch configuration table in accordance with some embodiments. The table corresponds to the exemplary configuration circuit of FIG. 2A with three uP-state signal lines defining seven enabled uP-state modes (State 1-State 7) and a spare/disabled state (State 8). As seen, each of the seven enabled states corresponds to an associated operating point frequency range. In turn, each enabled state, or frequency range, maps to a configuration mode, in this example, for two different configurable uarch circuits (Uarch Circuits A, B). It can be seen that every state does not necessarily correspond to a unique configuration for a uarch circuit. For example, Circuit A is in “FeatureA_ModeX” for States 2 through 6, is Off for State 1, and is in “FeatureA_ModeY” for State 7.

In some embodiments, The PPR (e.g., Cdyn/IPC ratio, change in Cdyn/change IPC ratio, etc.) may be calculated, estimated, and/or measured, for various potentially configurable uarch circuits. The ratio can then be used as a cost function to evaluate that circuit configuration's appropriateness for a given uarch performance (uP) state (operating point). Using this metric, the uarch configuration table may then be defined for the various uP-states and maintained in hardware. As a partition switches between uP states, the uarch configuration circuit(s) for the partition can index into this table and change the configuration of the configurable uarch circuit(s) to enable/disable uarch configurations.

FIG. 3 is a flow diagram showing a routine 301 for controlling uarch configuration based on configuration state in accordance with some embodiments. For example, this routine may be implemented by controller circuit 210 and/or global control circuit 112. At 302, configuration (or uP) state threshold levels are loaded into threshold memory, e.g., threshold registers.

At 304, feature configurations are updated in the uarch configuration table(s) and also, if appropriate, in configuration interface(s) such as with 255. For example, different configurations for different uarch circuits may be shifted to different configuration states, which themselves may be redefined to have different operating point ranges. And in some cases, new configurable uarch circuits may be added, e.g., to later design versions, or configuration definitions may be altered. In some embodiments, initial table and interface values may be programmed at the factory, e.g., with base values burned into fuses or the like. Thereafter, configuration values may be changed or added through BIOS updates or through other methods.

At 306, the routine determines if dynamic uarch configuration is to be active or disabled. If it is to be active, then at 308, it is activated, e.g., through a mux such as mux 240 from FIG. 2A and at 310, the appropriate configuration is set based on the current configuration state. From here, the routine loops back to decision block 306 and checks to see if dynamic uarch configuration is to remain active. If so, the routine continues to loop through 308, 310, and 306 unless and until at 306, it determines that dynamic configuration is to be disabled. If so, then at 312, dynamic configuration is disabled, and the routine loops back to 306 and proceeds as described.

### Example Architectures

Detailed below are descriptions of example computer architectures. Other system designs and configurations known in the arts for laptop, desktop, and handheld personal computers (PC)s, personal digital assistants, engineering workstations, servers, disaggregated servers, network devices, network hubs, switches, routers, embedded processors, digital signal processors (DSPs), graphics devices, video game devices, set-top boxes, micro controllers, cell phones, portable media players, hand-held devices, and various other electronic devices, are also suitable. In general, a variety of systems or electronic devices capable of incorporating a processor and/or other execution logic as disclosed herein are generally suitable.

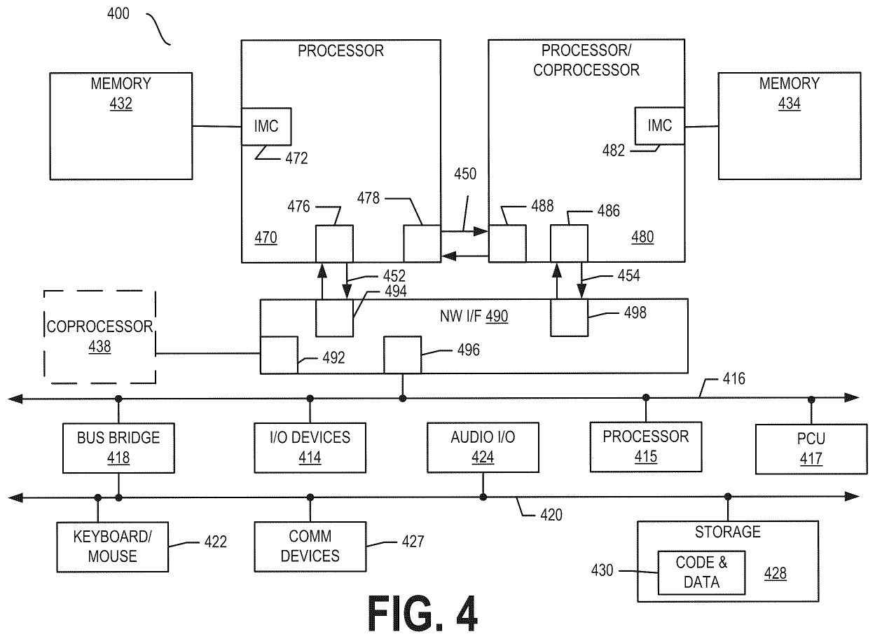

FIG. 4 illustrates an example computing system. Multiprocessor system 400 is an interfaced system and includes a plurality of processors or cores including a first processor 470 and a second processor 480 coupled via an interface 450 such as a point-to-point (P-P) interconnect, a fabric, and/or bus. In some examples, the first processor 470 and the second processor 480 are homogeneous. In some examples, first processor 470 and the second processor 480 are heterogenous. Though the example multiprocessor system 400 is shown to have two processors, the system may have three or more processors, or may be a single processor system. In some examples, the computing system is a system on a chip (SoC).

Processors 470 and 480 are shown including integrated memory controller (IMC) circuitry 472 and 482, respectively. Processor 470 also includes interface circuits 476 and 478; similarly, second processor 480 includes interface circuits 486 and 488. Processors 470, 480 may exchange information via the interface 450 using interface circuits 478, 488. IMCs 472 and 482 couple the processors 470, 480 to respective memories, namely a memory 432 and a memory 434, which may be portions of main memory locally attached to the respective processors.

Processors 470, 480 may each exchange information with a network interface (NW I/F) 490 via individual interfaces 452, 454 using interface circuits 476, 494, 486, 498. The network interface 490 (e.g., one or more of an interconnect, bus, and/or fabric, and in some examples is a chipset) may optionally exchange information with a co-processor 438 via an interface circuit 492. In some examples, the co-processor 438 is a special-purpose processor, such as, for example, a high-throughput processor, a network or communication processor, a compression engine, a graphics processor, a general purpose graphics processing unit (GPGPU), a neural-network processing unit (NPU), an embedded processor, a security processor, a cryptographic accelerator, a matrix accelerator, an in-memory analytics accelerator,, a data streaming accelerator, data graph operations, or the like.

A shared cache (not shown) may be included in either processor 470, 480 or outside of both processors, yet connected with the processors via an interface such as P-P interconnect, such that either or both processors'local cache information may be stored in the shared cache if a processor is placed into a low power mode.

Network interface 490 may be coupled to a first interface 416 via interface circuit 496. In some examples, first interface 416 may be an interface such as a Peripheral Component Interconnect (PCI) interconnect, a PCI Express interconnect or another I/O interconnect. In some examples, first interface 416 is coupled to a power control unit (PCU) 417, which may include circuitry, software, and/or firmware to perform power management operations with regard to the processors 470, 480 and/or co-processor 438. PCU 417 provides control information to a voltage regulator (not shown) to cause the voltage regulator to generate the appropriate regulated voltage. PCU 417 also provides control information to control the operating voltage generated. In various examples, PCU 417 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 417 is illustrated as being present as logic separate from the processor 470 and/or processor 480. In other cases, PCU 417 may execute on a given one or more of cores (not shown) of processor 470 or 480. In some cases, PCU 417 may be implemented as a microcontroller (dedicated or general-purpose) or other control logic configured to execute its own dedicated power management code, sometimes referred to as P-code. In yet other examples, power management operations to be performed by PCU 417 may be implemented externally to a processor, such as by way of a separate power management integrated circuit (PMIC) or another component external to the processor. In yet other examples, power management operations to be performed by PCU 417 may be implemented within BIOS or other system software.

Various I/O devices 414 may be coupled to first interface 416, along with a bus bridge 418 which couples first interface 416 to a second interface 420. In some examples, one or more additional processor(s) 415, such as co-processors, high throughput many integrated core (MIC) processors, GPGPUs, accelerators (such as graphics accelerators or digital signal processing (DSP) units), field programmable gate arrays (FPGAs), or any other processor, are coupled to first interface 416. In some examples, second interface 420 may be a low pin count (LPC) interface. Various devices may be coupled to second interface 420 including, for example, a keyboard and/or mouse 422, communication devices 427 and storage circuitry 428. Storage circuitry 428 may be one or more non-transitory machine-readable storage media as described below, such as a disk drive or other mass storage device which may include instructions/code and data 430. Further, an audio I/O 424 may be coupled to second interface 420. Note that other architectures than the point-to-point architecture described above are possible. For example, instead of the point-to-point architecture, a system such as multiprocessor system 400 may implement a multi-drop interface or other such architecture.

### Example Core Architectures, Processors, and Computer Architectures.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a co-processor including one or more special purpose cores intended primarily for graphics and/or scientific (throughput) computing. Such different processors lead to different computer system architectures, which may include: 1) the co-processor on a separate chip from the CPU; 2) the co-processor on a separate die in the same package as a CPU; 3) the co-processor on the same die as a CPU (in which case, such a co-processor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described co-processor, and additional functionality. Example core architectures are described next, followed by descriptions of example processors and computer architectures.

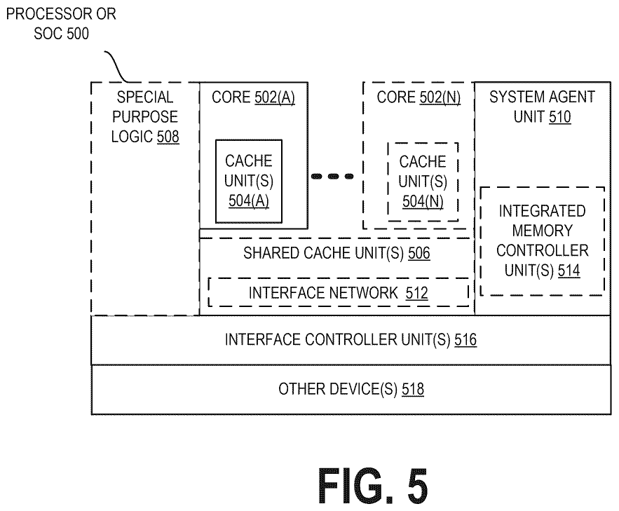

FIG. 5 illustrates a block diagram of an example processor and/or SoC 500 that may have one or more cores and an integrated memory controller. The solid lined boxes illustrate a processor and/or SoC 500 with a single core 502(A), system agent unit circuitry 510, and a set of one or more interface controller unit(s) circuitry 516, while the optional addition of the dashed lined boxes illustrates an alternative processor and/or SoC 500 with multiple cores 502(A)-(N), a set of one or more integrated memory controller unit(s) circuitry 514 in the system agent unit circuitry 510, and special purpose logic 508, as well as a set of one or more interface controller unit(s) circuitry 516. Note that the processor and/or SoC 500 may be one of the processors 470 or 480, or co-processor 438 or 415 of FIG. 4.

Thus, different implementations of the processor and/or SoC 500 may include: 1) a CPU with the special purpose logic 508 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 502(A)-(N) being one or more general purpose cores (e.g., general purpose in-order cores, general purpose out-of-order cores, or a combination of the two); 2) a co-processor with the cores 502(A)-(N) being a large number of special purpose cores intended primarily for graphics and/or scientific (throughput); and 3) a co-processor with the cores 502(A)-(N) being a large number of general purpose in-order cores. Thus, the processor and/or SoC 500 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 500 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 504(A)-(N) within the cores 502(A)-(N), a set of one or more shared cache unit(s) circuitry 506, and external memory (not shown) coupled to the set of integrated memory controller unit(s) circuitry 514. The set of one or more shared cache unit(s) circuitry 506 may include one or more mid-level caches, such as level 2 (L2), level 3 (L3), level 4 (L4), or other levels of cache, such as a last level cache (LLC), and/or combinations thereof. While in some examples interface network circuitry 512 (e.g., a ring interconnect) interfaces the special purpose logic 508 (e.g., integrated graphics logic), the set of shared cache unit(s) circuitry 506, and the system agent unit circuitry 510, alternative examples use any number of well-known techniques for interfacing such units. In some examples, coherency is maintained between one or more of the shared cache unit(s) circuitry 506 and cores 502(A)-(N). In some examples, interface controller unit(s) circuitry 516 couple the cores 502(A)-(N) to one or more other devices 518 such as one or more I/O devices, storage, one or more communication devices (e.g., wireless networking, wired networking, etc.), etc.

In some examples, one or more of the cores 502(A)-(N) are capable of multi-threading. The system agent unit circuitry 510 includes those components coordinating and operating cores 502(A)-(N). The system agent unit circuitry 510 may include, for example, power control unit (PCU) circuitry and/or display unit circuitry (not shown). The PCU may be or may include logic and components needed for regulating the power state of the cores 502(A)-(N) and/or the special purpose logic 508 (e.g., integrated graphics logic). The display unit circuitry is for driving one or more externally connected displays.

The cores 502(A)-(N) may be homogenous in terms of instruction set architecture (ISA). Alternatively, the cores 502(A)-(N) may be heterogeneous in terms of ISA; that is, a subset of the cores 502(A)-(N) may be capable of executing an ISA, while other cores may be capable of executing only a subset of that ISA or another ISA.

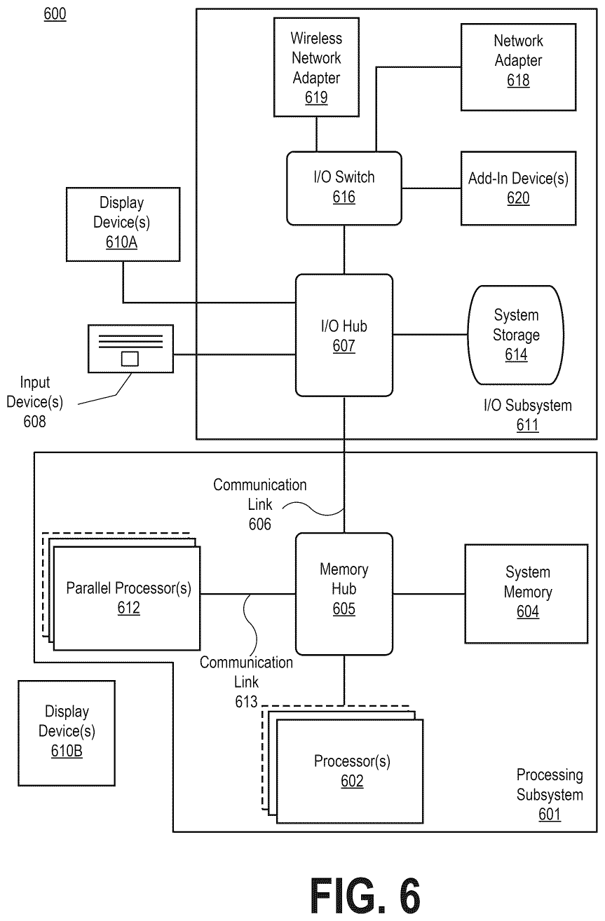

FIG. 6 is a block diagram illustrating a computing system 600 configured to implement one or more aspects of the examples described herein. The computing system 600 includes a processing subsystem 601 having one or more processor(s) 602 and a system memory 604 communicating via an interconnection path that may include a memory hub 605. The memory hub 605 may be a separate component within a chipset component or may be integrated within the one or more processor(s) 602. The memory hub 605 couples with an I/O subsystem 611 via a communication link 606. The I/O subsystem 611 includes an I/O hub 607 that can enable the computing system 600 to receive input from one or more input device(s) 608. Additionally, the I/O hub 607 can enable a display controller, which may be included in the one or more processor(s) 602, to provide outputs to one or more display device(s) 610A. In some examples the one or more display device(s) 610A coupled with the I/O hub 607 can include a local, internal, or embedded display device.

The processing subsystem 601, for example, includes one or more parallel processor(s) 612 coupled to memory hub 605 via a bus or communication link 613. The communication link 613 may be one of any number of standards-based communication link technologies or protocols, such as, but not limited to PCI Express, or may be a vendor specific communications interface or communications fabric. The one or more parallel processor(s) 612 may form a computationally focused parallel or vector processing system that can include a large number of processing cores and/or processing clusters, such as a many integrated core (MIC) processor. For example, the one or more parallel processor(s) 612 form a graphics processing subsystem that can output pixels to one of the one or more display device(s) 610A coupled via the I/O hub 607. The one or more parallel processor(s) 612 can also include a display controller and display interface (not shown) to enable a direct connection to one or more display device(s) 610B.

Within the I/O subsystem 611, a system storage unit 614 can connect to the I/O hub 607 to provide a storage mechanism for the computing system 600. An I/O switch 616 can be used to provide an interface mechanism to enable connections between the I/O hub 607 and other components, such as a network adapter 618 and/or wireless network adapter 619 that may be integrated into the platform, and various other devices that can be added via one or more add-in device(s) 620. The add-in device(s) 620 may also include, for example, one or more external graphics processor devices, graphics cards, and/or compute accelerators. The network adapter 618 can be an Ethernet adapter or another wired network adapter. The wireless network adapter 619 can include one or more of a Wi-Fi, Bluetooth, near field communication (NFC), or other network device that includes one or more wireless radios.

The computing system 600 can include other components not explicitly shown, including USB or other port connections, optical storage drives, video capture devices, and the like, which may also be connected to the I/O hub 607. Communication paths interconnecting the various components in FIG. 6 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL. mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 612 may incorporate circuitry optimized for graphics and video processing, including, for example, video output circuitry, and constitutes a graphics processing unit (GPU). Alternatively or additionally, the one or more parallel processor(s) 612 can incorporate circuitry optimized for general purpose processing, while preserving the underlying computational architecture, described in greater detail herein. Components of the computing system 600 may be integrated with one or more other system elements on a single integrated circuit. For example, the one or more parallel processor(s) 612, memory hub 605, processor(s) 602, and I/O hub 607 can be integrated into a system on chip (SoC) integrated circuit. Alternatively, the components of the computing system 600 can be integrated into a single package to form a system in package (SIP) configuration. In some examples at least a portion of the components of the computing system 600 can be integrated into a multi-chip module (MCM), which can be interconnected with other multi-chip modules into a modular computing system.

It will be appreciated that the computing system 600 shown herein is illustrative and that variations and modifications are possible. The connection topology, including the number and arrangement of bridges, the number of processor(s) 602, and the number of parallel processor(s) 612, may be modified as desired. For instance, system memory 604 can be connected to the processor(s) 602 directly rather than through a bridge, while other devices communicate with system memory 604 via the memory hub 605 and the processor(s) 602. In other alternative topologies, the parallel processor(s) 612 are connected to the I/O hub 607 or directly to one of the one or more processor(s) 602, rather than to the memory hub 605. In other examples, the I/O hub 607 and memory hub 605 may be integrated into a single chip. It is also possible that two or more sets of processor(s) 602 are attached via multiple sockets, which can couple with two or more instances of the parallel processor(s) 612.

Some of the particular components shown herein are optional and may not be included in all implementations of the computing system 600. For example, any number of add-in cards or peripherals may be supported, or some components may be eliminated. Furthermore, some architectures may use different terminology for components similar to those illustrated in FIG. 6. For example, the memory hub 605 may be referred to as a Northbridge in some architectures, while the I/O hub 607 may be referred to as a Southbridge.

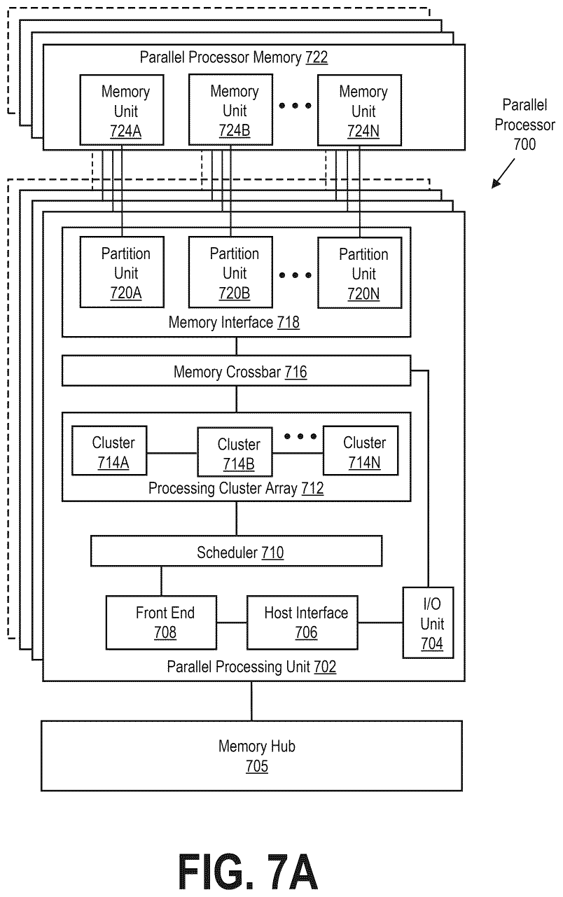

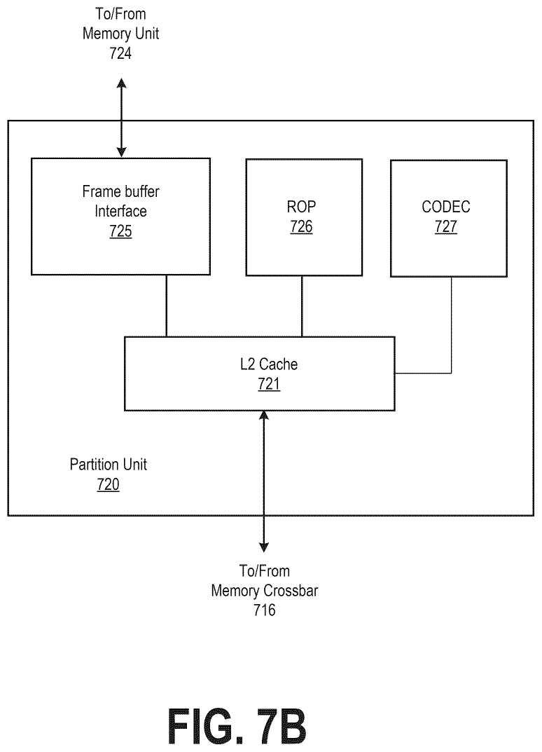

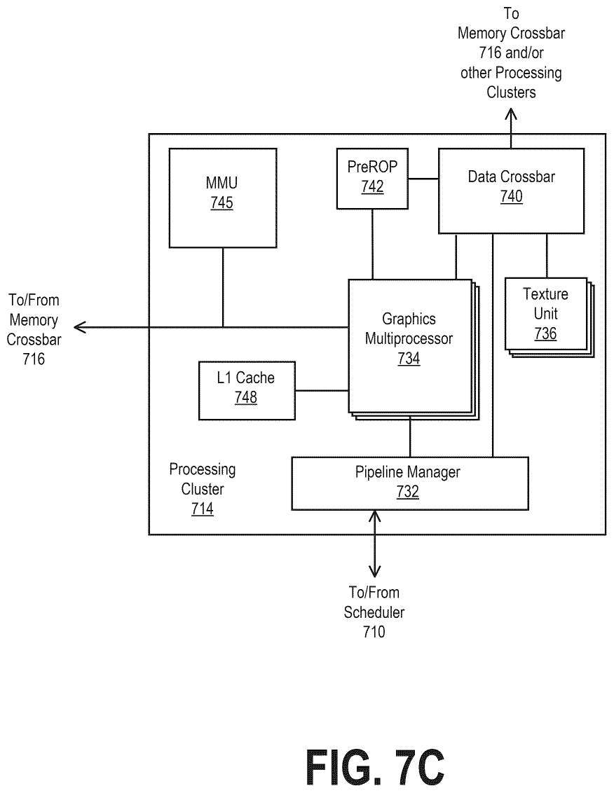

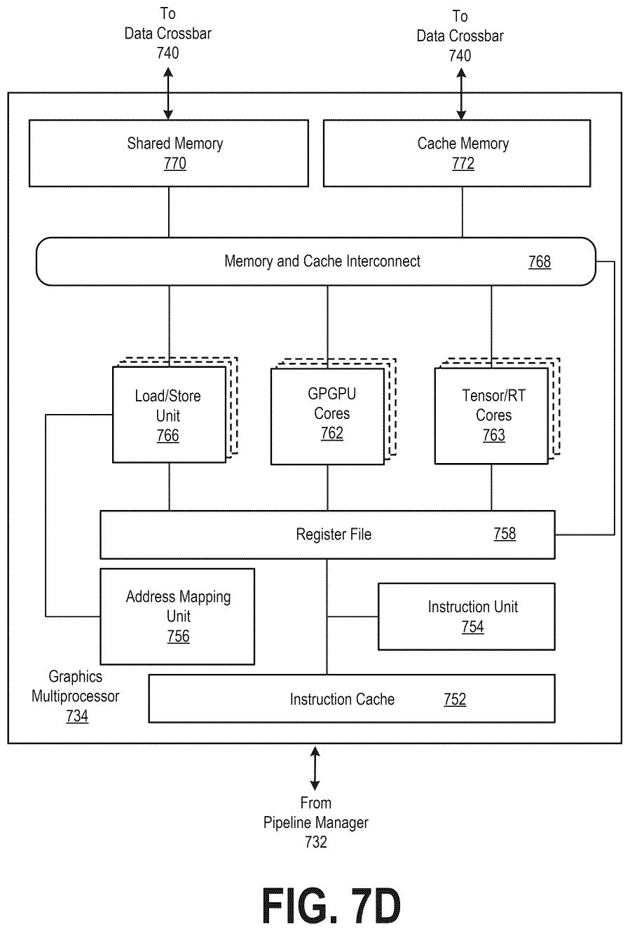

FIG. 7A illustrates examples of a parallel processor 700. The parallel processor 700 may be a GPU, GPGPU or the like as described herein. The various components of the parallel processor 700 may be implemented using one or more integrated circuit devices, such as programmable processors, application specific integrated circuits (ASICs), or field programmable gate arrays (FPGA). The parallel processor 700 may be one or more of the parallel processor(s) 612 shown in FIG. 6.

The parallel processor 700 includes a parallel processing unit 702. The parallel processing unit includes an I/O unit 704 that enables communication with other devices, including other instances of the parallel processing unit 702. The I/O unit 704 may be directly connected to other devices. For instance, the I/O unit 704 connects with other devices via the use of a hub or switch interface, such as memory hub 605. The connections between the memory hub 605 and the I/O unit 704 form a communication link 613. Within the parallel processing unit 702, the I/O unit 704 connects with a host interface 706 and a memory crossbar 716, where the host interface 706 receives commands directed to performing processing operations and the memory crossbar 716 receives commands directed to performing memory operations.

When the host interface 706 receives a command buffer via the I/O unit 704, the host interface 706 can direct work operations to perform those commands to a front end 708. In some examples the front end 708 couples with a scheduler 710, which is configured to distribute commands or other work items to a processing cluster array 712. The scheduler 710 ensures that the processing cluster array 712 is properly configured and in a valid state before tasks are distributed to the processing clusters of the processing cluster array 712. The scheduler 710 may be implemented via firmware logic executing on a microcontroller. The microcontroller implemented scheduler 710 is configurable to perform complex scheduling and work distribution operations at coarse and fine granularity, enabling rapid preemption and context switching of threads executing on the processing cluster array 712. Preferably, the host software can prove workloads for scheduling on the processing cluster array 712 via one of multiple graphics processing doorbells. In other examples, polling for new workloads or interrupts can be used to identify or indicate availability of work to perform. The workloads can then be automatically distributed across the processing cluster array 712 by the scheduler 710 logic within the scheduler microcontroller.

The processing cluster array 712 can include up to “N” processing clusters (e.g., cluster 714A, cluster 714B, through cluster 714N). Each cluster 714A-714N of the processing cluster array 712 can execute a large number of concurrent threads. The scheduler 710 can allocate work to the clusters 714A-714N of the processing cluster array 712 using various scheduling and/or work distribution algorithms, which may vary depending on the workload arising for each type of program or computation. The scheduling can be handled dynamically by the scheduler 710 or can be assisted in part by compiler logic during compilation of program logic configured for execution by the processing cluster array 712. Optionally, different clusters 714A-714N of the processing cluster array 712 can be allocated for processing different types of programs or for performing different types of computations.

The processing cluster array 712 can be configured to perform various types of parallel processing operations. For example, the processing cluster array 712 is configured to perform general-purpose parallel compute operations. For example, the processing cluster array 712 can include logic to execute processing tasks including filtering of video and/or audio data, performing modeling operations, including physics operations, and performing data transformations.

The processing cluster array 712 is configured to perform parallel graphics processing operations. In such examples in which the parallel processor 700 is configured to perform graphics processing operations, the processing cluster array 712 can include additional logic to support the execution of such graphics processing operations, including, but not limited to texture sampling logic to perform texture operations, as well as tessellation logic and other vertex processing logic. Additionally, the processing cluster array 712 can be configured to execute graphics processing related shader programs such as, but not limited to vertex shaders, tessellation shaders, geometry shaders, and pixel shaders. The parallel processing unit 702 can transfer data from system memory via the I/O unit 704 for processing. During processing the transferred data can be stored to on-chip memory (e.g., parallel processor memory 722) during processing, then written back to system memory.

In examples in which the parallel processing unit 702 is used to perform graphics processing, the scheduler 710 may be configured to divide the processing workload into approximately equal sized tasks, to better enable distribution of the graphics processing operations to multiple clusters 714A-714N of the processing cluster array 712. In some of these examples, portions of the processing cluster array 712 can be configured to perform different types of processing. For example, a first portion may be configured to perform vertex shading and topology generation, a second portion may be configured to perform tessellation and geometry shading, and a third portion may be configured to perform pixel shading or other screen space operations, to produce a rendered image for display. Intermediate data produced by one or more of the clusters 714A-714N may be stored in buffers to allow the intermediate data to be transmitted between clusters 714A-714N for further processing.

During operation, the processing cluster array 712 can receive processing tasks to be executed via the scheduler 710, which receives commands defining processing tasks from front end 708. For graphics processing operations, processing tasks can include indices of data to be processed, e.g., surface (patch) data, primitive data, vertex data, and/or pixel data, as well as state parameters and commands defining how the data is to be processed (e.g., what program is to be executed). The scheduler 710 may be configured to fetch the indices corresponding to the tasks or may receive the indices from the front end 708. The front end 708 can be configured to ensure the processing cluster array 712 is configured to a valid state before the workload specified by incoming command buffers (e.g., batch-buffers, push buffers, etc.) is initiated.

Each of the one or more instances of the parallel processing unit 702 can couple with parallel processor memory 722. The parallel processor memory 722 can be accessed via the memory crossbar 716, which can receive memory requests from the processing cluster array 712 as well as the I/O unit 704. The memory crossbar 716 can access the parallel processor memory 722 via a memory interface 718. The memory interface 718 can include multiple partition units (e.g., partition unit 720A, partition unit 720B, through partition unit 720N) that can each couple to a portion (e.g., memory unit) of parallel processor memory 722. The number of partition units 720A-720N may be configured to be equal to the number of memory units, such that a first partition unit 720A has a corresponding first memory unit 724A, a second partition unit 720B has a corresponding second memory unit 724B, and an Nth partition unit 720N has a corresponding Nth memory unit 724N. In other examples, the number of partition units 720A-720N may not be equal to the number of memory devices.

The memory units 724A-724N can include various types of memory devices, including dynamic random-access memory (DRAM) or graphics random access memory, such as synchronous graphics random access memory (SGRAM), including graphics double data rate (GDDR) memory. Optionally, the memory units 724A-724N may also include 3D stacked memory, including but not limited to high bandwidth memory (HBM). Persons skilled in the art will appreciate that the specific implementation of the memory units 724A-724N can vary and can be selected from one of various conventional designs. Render targets, such as frame buffers or texture maps may be stored across the memory units 724A-724N, allowing partition units 720A-720N to write portions of each render target in parallel to efficiently use the available bandwidth of parallel processor memory 722. In some examples, a local instance of the parallel processor memory 722 may be excluded in favor of a unified memory design that utilizes system memory in conjunction with local cache memory.

Optionally, any one of the clusters 714A-714N of the processing cluster array 712 has the ability to process data that will be written to any of the memory units 724A-724N within parallel processor memory 722. The memory crossbar 716 can be configured to transfer the output of each cluster 714A-714N to any partition unit 720A-720N or to another cluster 714A-714N, which can perform additional processing operations on the output. Each cluster 714A-714N can communicate with the memory interface 718 through the memory crossbar 716 to read from or write to various external memory devices. In one of the examples with the memory crossbar 716 the memory crossbar 716 has a connection to the memory interface 718 to communicate with the I/O unit 704, as well as a connection to a local instance of the parallel processor memory 722, enabling the processing units within the different processing clusters 714A-714N to communicate with system memory or other memory that is not local to the parallel processing unit 702. Generally, the memory crossbar 716 may, for example, be able to use virtual channels to separate traffic streams between the clusters 714A-714N and the partition units 720A-720N.

While a single instance of the parallel processing unit 702 is illustrated within the parallel processor 700, any number of instances of the parallel processing unit 702 can be included. For example, multiple instances of the parallel processing unit 702 can be provided on a single add-in card, or multiple add-in cards can be interconnected. For example, the parallel processor 700 can be an add-in device, such as add-in device(s) 620 of FIG. 6, which may be a graphics card such as a discrete graphics card that includes one or more GPUs, one or more memory devices, and device-to-device or network or fabric interfaces. The different instances of the parallel processing unit 702 can be configured to inter-operate even if the different instances have different numbers of processing cores, different amounts of local parallel processor memory, and/or other configuration differences. Optionally, some instances of the parallel processing unit 702 can include higher precision floating point units relative to other instances. Systems incorporating one or more instances of the parallel processing unit 702 or the parallel processor 700 can be implemented in a variety of configurations and form factors, including but not limited to desktop, laptop, or handheld personal computers, servers, workstations, game consoles, and/or embedded systems. An orchestrator can form composite nodes for workload performance using one or more of: disaggregated processor resources, cache resources, memory resources, storage resources, and networking resources.

In some examples, the parallel processing unit 702 can be partitioned into multiple instances. Those multiple instances can be configured to execute workloads associated with different clients in an isolated manner, enabling a pre-determined quality of service to be provided for each client. For example, each cluster 714A-714N can be compartmentalized and isolated from other clusters, allowing the processing cluster array 712 to be divided into multiple compute partitions or instances. In such configuration, workloads that execute on an isolated partition are protected from faults or errors associated with a different workload that executes on a different partition. The partition units 720A-720N can be configured to enable a dedicated and/or isolated path to memory for the clusters 714A-714N associated with the respective compute partitions. This datapath isolation enables the compute resources within a partition can communicate with one or more assigned memory units 724A-724N without being subjected to inference by the activities of other partitions.

FIG. 7B is a block diagram of a partition unit 720. The partition unit 720 may be an instance of one of the partition units 720A-720N of FIG. 7A. As illustrated, the partition unit 720 includes an L2 cache 721, a frame buffer interface 725, and a ROP 726 (raster operations unit). The L2 cache 721 is a read/write cache that is configured to perform load and store operations received from the memory crossbar 716 and ROP 726. Read misses and urgent write-back requests are output by L2 cache 721 to frame buffer interface 725 for processing. Updates can also be sent to the frame buffer via the frame buffer interface 725 for processing. In some examples the frame buffer interface 725 interfaces with one of the memory units in parallel processor memory, such as the memory units 724A-724N of FIG. 7A (e.g., within parallel processor memory 722). The partition unit 720 may additionally or alternatively also interface with one of the memory units in parallel processor memory via a memory controller (not shown).

In graphics applications, the ROP 726 is a processing unit that performs raster operations such as stencil, z test, blending, and the like. The ROP 726 then outputs processed graphics data that is stored in graphics memory. In some examples the ROP 726 includes or couples with a CODEC 727 that includes compression logic to compress depth or color data that is written to memory or the L2 cache 721 and decompress depth or color data that is read from memory or the L2 cache 721. The compression logic can be lossless compression logic that makes use of one or more of multiple compression algorithms. The type of compression that is performed by the CODEC 727 can vary based on the statistical characteristics of the data to be compressed. For example, in some examples, delta color compression is performed on depth and color data on a per-tile basis. In some examples the CODEC 727 includes compression and decompression logic that can compress and decompress compute data associated with machine learning operations. The CODEC 727 can, for example, compress sparse matrix data for sparse machine learning operations. The CODEC 727 can also compress sparse matrix data that is encoded in a sparse matrix format (e.g., coordinate list encoding (COO), compressed sparse row (CSR), compress sparse column (CSC), etc.) to generate compressed and encoded sparse matrix data. The compressed and encoded sparse matrix data can be decompressed and/or decoded before being processed by processing elements or the processing elements can be configured to consume compressed, encoded, or compressed and encoded data for processing.

The ROP 726 may be included within each processing cluster (e.g., cluster 714A-714N of FIG. 7A) instead of within the partition unit 720. In such example, read and write requests for pixel data are transmitted over the memory crossbar 716 instead of pixel fragment data. The processed graphics data may be displayed on a display device, such as one of the one or more display device(s) 610A-610B of FIG. 6, routed for further processing by the processor(s) 602, or routed for further processing by one of the processing entities within the parallel processor 700 of FIG. 7A.

FIG. 7C is a block diagram of a processing cluster 714 within a parallel processing unit. For example, the processing cluster is an instance of one of the processing clusters 714A-714N of FIG. 7A. The processing cluster 714 can be configured to execute many threads in parallel, where the term “thread” refers to an instance of a particular program executing on a particular set of input data. Optionally, single-instruction, multiple-data (SIMD) instruction issue techniques may be used to support parallel execution of a large number of threads without providing multiple independent instruction units. Alternatively, single-instruction, multiple-thread (SIMT) techniques may be used to support parallel execution of a large number of generally synchronized threads, using a common instruction unit configured to issue instructions to a set of processing engines within each one of the processing clusters. Unlike a SIMD execution regime, where all processing engines typically execute identical instructions, SIMT execution allows different threads to more readily follow divergent execution paths through a given thread program. Persons skilled in the art will understand that a SIMD processing regime represents a functional subset of a SIMT processing regime.

Operation of the processing cluster 714 can be controlled via a pipeline manager 732 that distributes processing tasks to SIMT parallel processors. The pipeline manager 732 receives instructions from the scheduler 710 of FIG. 7A and manages execution of those instructions via a graphics multiprocessor 734 and/or a texture unit 736. The graphics multiprocessor 734 is an exemplary instance of a SIMT parallel processor. However, various types of SIMT parallel processors of differing architectures may be included within the processing cluster 714. One or more instances of the graphics multiprocessor 734 can be included within a processing cluster 714. The graphics multiprocessor 734 can process data and a data crossbar 740 can be used to distribute the processed data to one of multiple possible destinations, including other shader units. The pipeline manager 732 can facilitate the distribution of processed data by specifying destinations for processed data to be distributed via the data crossbar 740.

Each graphics multiprocessor 734 within the processing cluster 714 can include an identical set of functional execution logic (e.g., arithmetic logic units, load-store units, etc.). The functional execution logic can be configured in a pipelined manner in which new instructions can be issued before previous instructions are complete. The functional execution logic supports a variety of operations including integer and floating-point arithmetic, comparison operations, Boolean operations, bit-shifting, and computation of various algebraic functions. The same functional-unit hardware could be leveraged to perform different operations and any combination of functional units may be present.

The instructions transmitted to the processing cluster 714 constitute a thread. A set of threads executing across the set of parallel processing engines is a thread group. A thread group executes the same program on different input data. Each thread within a thread group can be assigned to a different processing engine within a graphics multiprocessor 734. A thread group may include fewer threads than the number of processing engines within the graphics multiprocessor 734. When a thread group includes fewer threads than the number of processing engines, one or more of the processing engines may be idle during cycles in which that thread group is being processed. A thread group may also include more threads than the number of processing engines within the graphics multiprocessor 734. When the thread group includes more threads than the number of processing engines within the graphics multiprocessor 734, processing can be performed over consecutive clock cycles. Optionally, multiple thread groups can be executed concurrently on the graphics multiprocessor 734.

The graphics multiprocessor 734 may include an internal cache memory to perform load and store operations. Optionally, the graphics multiprocessor 734 can forego an internal cache and use a cache memory (e.g., level 1 (L1) cache 748) within the processing cluster 714. Each graphics multiprocessor 734 also has access to level 2 (L2) caches within the partition units (e.g., partition units 720A-720N of FIG. 7A) that are shared among all processing clusters 714 and may be used to transfer data between threads. The graphics multiprocessor 734 may also access off-chip global memory, which can include one or more of local parallel processor memory and/or system memory. Any memory external to the parallel processing unit 702 may be used as global memory. Embodiments in which the processing cluster 714 includes multiple instances of the graphics multiprocessor 734 can share common instructions and data, which may be stored in the L1 cache 748.

Each processing cluster 714 may include an MMU 745 (memory management unit) that is configured to map virtual addresses into physical addresses. In other examples, one or more instances of the MMU 745 may reside within the memory interface 718 of FIG. 7A. The MMU 745 includes a set of page table entries (PTEs) used to map a virtual address to a physical address of a tile and optionally a cache line index. The MMU 745 may include address translation lookaside buffers (TLB) or caches that may reside within the graphics multiprocessor 734 or the L1 cache 748 of processing cluster 714. The physical address is processed to distribute surface data access locality to allow efficient request interleaving among partition units. The cache line index may be used to determine whether a request for a cache line is a hit or miss.

In graphics and computing applications, a processing cluster 714 may be configured such that each graphics multiprocessor 734 is coupled to a texture unit 736 for performing texture mapping operations, e.g., determining texture sample positions, reading texture data, and filtering the texture data. Texture data is read from an internal texture L1 cache (not shown) or in some examples from the L1 cache within graphics multiprocessor 734 and is fetched from an L2 cache, local parallel processor memory, or system memory, as needed. Each graphics multiprocessor 734 outputs processed tasks to the data crossbar 740 to provide the processed task to another processing cluster 714 for further processing or to store the processed task in an L2 cache, local parallel processor memory, or system memory via the memory crossbar 716. A preROP 742 (pre-raster operations unit) is configured to receive data from graphics multiprocessor 734, direct data to ROP units, which may be located with partition units as described herein (e.g., partition units 720A-720N of FIG. 7A). The preROP 742 unit can perform optimizations for color blending, organize pixel color data, and perform address translations.

It will be appreciated that the core architecture described herein is illustrative and that variations and modifications are possible. Any number of processing units, e.g., graphics multiprocessor 734, texture units 736, preROPs 742, etc., may be included within a processing cluster 714. Further, while only one processing cluster 714 is shown, a parallel processing unit as described herein may include any number of instances of the processing cluster 714. Optionally, each processing cluster 714 can be configured to operate independently of other processing clusters 714 using separate and distinct processing units, L1 caches, L2 caches, etc.

FIG. 7D shows an example of the graphics multiprocessor 734 in which the graphics multiprocessor 734 couples with the pipeline manager 732 of the processing cluster 714. The graphics multiprocessor 734 has an execution pipeline including but not limited to an instruction cache 752, an instruction unit 754, an address mapping unit 756, a register file 758, one or more general purpose graphics processing unit (GPGPU) cores 762, and one or more load/store units 766. The GPGPU cores 762 and load/store units 766 are coupled with cache memory 772 and shared memory 770 via a memory and cache interconnect 768. The graphics multiprocessor 734 may additionally include tensor and/or ray-tracing cores 763 that include hardware logic to accelerate matrix and/or ray-tracing operations.

The instruction cache 752 may receive a stream of instructions to execute from the pipeline manager 732. The instructions are cached in the instruction cache 752 and dispatched for execution by the instruction unit 754. The instruction unit 754 can dispatch instructions as thread groups (e.g., warps), with each thread of the thread group assigned to a different execution unit within GPGPU core 762. An instruction can access any of a local, shared, or global address space by specifying an address within a unified address space. The address mapping unit 756 can be used to translate addresses in the unified address space into a distinct memory address that can be accessed by the load/store units 766.

The register file 758 provides a set of registers for the functional units of the graphics multiprocessor 734. The register file 758 provides temporary storage for operands connected to the data paths of the functional units (e.g., GPGPU cores 762, load/store units 766) of the graphics multiprocessor 734. The register file 758 may be divided between each of the functional units such that each functional unit is allocated a dedicated portion of the register file 758. For example, the register file 758 may be divided between the different warps being executed by the graphics multiprocessor 734.

The GPGPU cores 762 can each include floating point units (FPUs) and/or integer arithmetic logic units (ALUs) that are used to execute instructions of the graphics multiprocessor 734. In some implementations, the GPGPU cores 762 can include hardware logic that may otherwise reside within the tensor and/or ray-tracing cores 763. The GPGPU cores 762 can be similar in architecture or can differ in architecture. For example and in some examples, a first portion of the GPGPU cores 762 include a single precision FPU and an integer ALU while a second portion of the GPGPU cores include a double precision FPU. Optionally, the FPUs can implement the IEEE 754-2008 standard for floating point arithmetic or enable variable precision floating point arithmetic. The graphics multiprocessor 734 can additionally include one or more fixed function or special function units to perform specific functions such as copy rectangle or pixel blending operations. One or more of the GPGPU cores can also include fixed or special function logic.

The GPGPU cores 762 may include SIMD logic capable of performing a single instruction on multiple sets of data. Optionally, GPGPU cores 762 can physically execute SIMD4, SIMD8, and SIMD16 instructions and logically execute SIMD1, SIMD2, and SIMD32 instructions. The SIMD instructions for the GPGPU cores can be generated at compile time by a shader compiler or automatically generated when executing programs written and compiled for single program multiple data (SPMD) or SIMT architectures. Multiple threads of a program configured for the SIMT execution model can be executed via a single SIMD instruction. For example and in some examples, eight SIMT threads that perform the same or similar operations can be executed in parallel via a single SIMD8 logic unit.

The memory and cache interconnect 768 is an interconnect network that connects each of the functional units of the graphics multiprocessor 734 to the register file 758 and to the shared memory 770. For example, the memory and cache interconnect 768 is a crossbar interconnect that allows the load/store unit 766 to implement load and store operations between the shared memory 770 and the register file 758. The register file 758 can operate at the same frequency as the GPGPU cores 762, thus data transfer between the GPGPU cores 762 and the register file 758 is very low latency. The shared memory 770 can be used to enable communication between threads that execute on the functional units within the graphics multiprocessor 734. The cache memory 772 can be used as a data cache for example, to cache texture data communicated between the functional units and the texture unit 736. The shared memory 770 can also be used as a program managed cached. The shared memory 770 and the cache memory 772 can couple with the data crossbar 740 to enable communication with other components of the processing cluster. Threads executing on the GPGPU cores 762 can programmatically store data within the shared memory in addition to the automatically cached data that is stored within the cache memory 772.

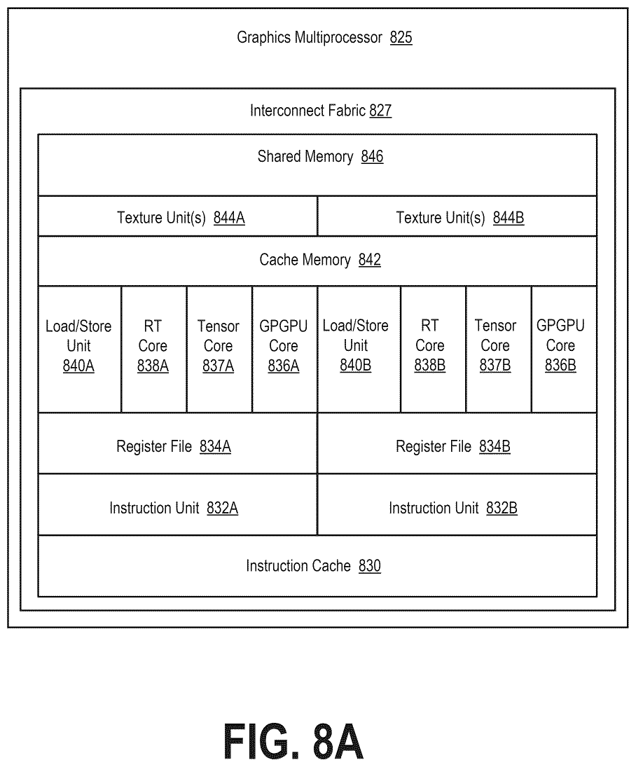

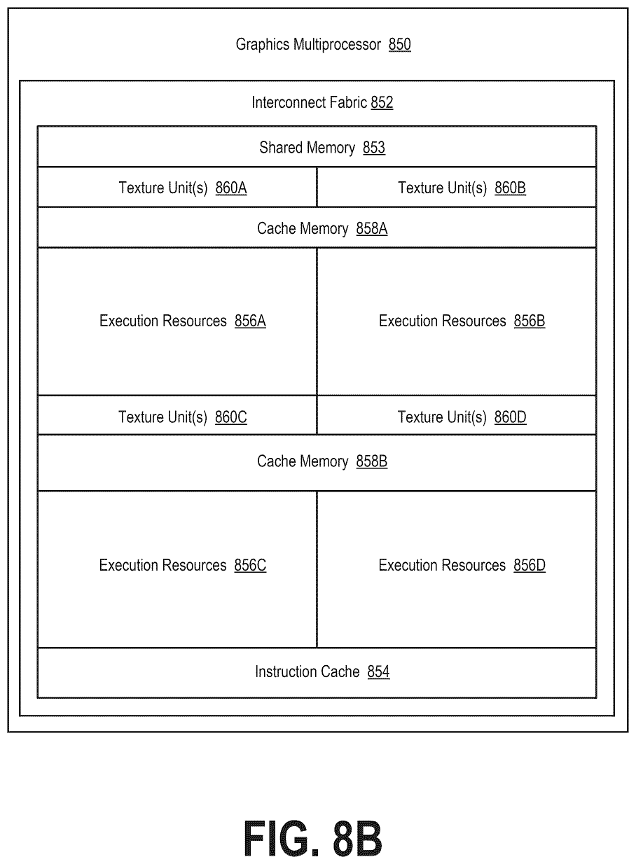

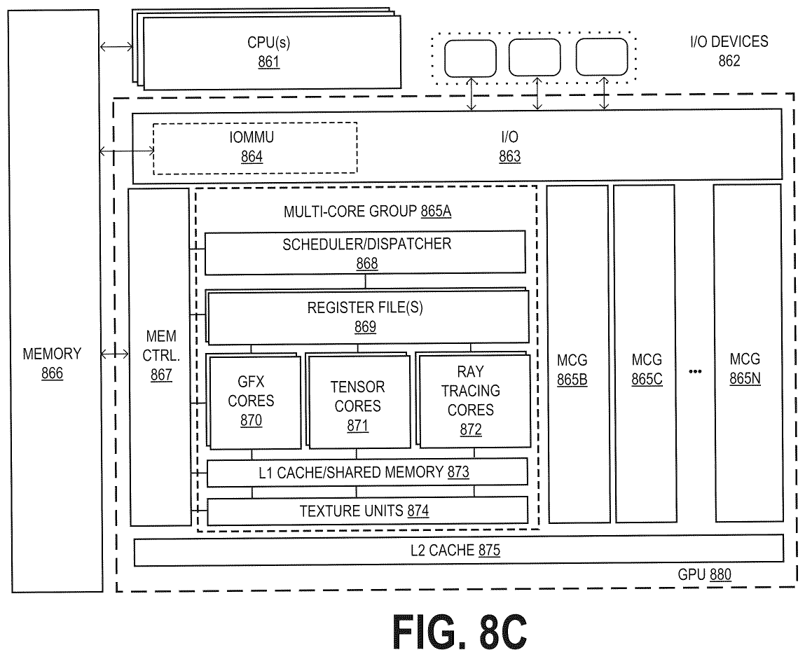

FIGS. 8A-8C illustrate additional graphics multiprocessors, according to examples. FIG. 8A-8B illustrate graphics multiprocessors 825, 850, which are related to the graphics multiprocessor 734 of FIG. 7C and may be used in place of one of those. Therefore, the disclosure of any features in combination with the graphics multiprocessor 734 herein also discloses a corresponding combination with the graphics multiprocessors 825, 850, but is not limited to such. FIG. 8C illustrates a graphics processing unit (GPU) 880 which includes dedicated sets of graphics processing resources arranged into multi-core groups 865A-865N, which correspond to the graphics multiprocessors 825, 850. The illustrated graphics multiprocessors 825, 850 and the multi-core groups 865A-865N can be streaming multiprocessors (SM) capable of simultaneous execution of a large number of execution threads.

The graphics multiprocessor 825 of FIG. 8A includes multiple additional instances of execution resource units relative to the graphics multiprocessor 734 of FIG. 7D. For example, the graphics multiprocessor 825 can include multiple instances of the instruction unit 832A-832B, register file 834A-834B, and texture unit(s) 844A-844B. The graphics multiprocessor 825 also includes multiple sets of graphics or compute execution units (e.g., GPGPU core 836A-836B, tensor core 837A-837B, ray-tracing core 838A-838B) and multiple sets of load/store units 840A-840B. The execution resource units have a common instruction cache 830, texture and/or data cache memory 842, and shared memory 846.

The various components can communicate via an interconnect fabric 827. The interconnect fabric 827 may include one or more crossbar switches to enable communication between the various components of the graphics multiprocessor 825. The interconnect fabric 827 may be a separate, high-speed network fabric layer upon which each component of the graphics multiprocessor 825 is stacked. The components of the graphics multiprocessor 825 communicate with remote components via the interconnect fabric 827. For example, the cores 836A-836B, 837A-837B, and 838A-838B can each communicate with shared memory 846 via the interconnect fabric 827. The interconnect fabric 827 can arbitrate communication within the graphics multiprocessor 825 to ensure a fair bandwidth allocation between components.

The graphics multiprocessor 850 of FIG. 8B includes multiple sets of execution resources 856A-856D, where each set of execution resource includes multiple instruction units, register files, GPGPU cores, and load store units, as illustrated in FIG. 7D and FIG. 8A. The execution resources 856A-856D can work in concert with texture unit(s) 860A-860D for texture operations, while sharing an instruction cache 854, and shared memory 853. For example, the execution resources 856A-856D can share an instruction cache 854 and shared memory 853, as well as multiple instances of a texture and/or data cache memory 858A-858B. The various components can communicate via an interconnect fabric 852 similar to the interconnect fabric 827 of FIG. 8A.

Persons skilled in the art will understand that the architecture described in FIG. 1, 7A-7D, and 8A-8B are descriptive and not limiting as to the scope of the present examples. Thus, the techniques described herein may be implemented on any properly configured processing unit, including, without limitation, one or more mobile application processors, one or more desktop or server central processing units (CPUs) including multi-core CPUs, one or more parallel processing units, such as the parallel processing unit 702 of FIG. 7A, as well as one or more graphics processors or special purpose processing units, without departure from the scope of the examples described herein.

The parallel processor or GPGPU as described herein may be communicatively coupled to host/processor cores to accelerate graphics operations, machine-learning operations, pattern analysis operations, and various general-purpose GPU (GPGPU) functions. The GPU may be communicatively coupled to the host processor/cores over a bus or other interconnect (e.g., a high-speed interconnect such as PCIe, NVLink, or other known protocols, standardized protocols, or proprietary protocols). In other examples, the GPU may be integrated on the same package or chip as the cores and communicatively coupled to the cores over an internal processor bus/interconnect (i.e., internal to the package or chip). Regardless of the manner in which the GPU is connected, the processor cores may allocate work to the GPU in the form of sequences of commands/instructions contained in a work descriptor. The GPU then uses dedicated circuitry/logic for efficiently processing these commands/instructions.

FIG. 8C illustrates a graphics processing unit (GPU) 880 which includes dedicated sets of graphics processing resources arranged into multi-core groups 865A-865N. While the details of only a single multi-core group 865A are provided, it will be appreciated that the other multi-core groups 865B-865N may be equipped with the same or similar sets of graphics processing resources. Details described with respect to the multi-core groups 865A-865N may also apply to any graphics multiprocessor 734, 825, 850 described herein.

As illustrated, a multi-core group 865A may include a set of graphics cores 870, a set of tensor cores 871, and a set of ray tracing cores 872. A scheduler/dispatcher 868 schedules and dispatches the graphics threads for execution on the various cores 870, 871, 872. A set of register files 869 store operand values used by the cores 870, 871, 872 when executing the graphics threads. These may include, for example, integer registers for storing integer values, floating point registers for storing floating point values, vector registers for storing packed data elements (integer and/or floating-point data elements) and tile registers for storing tensor/matrix values. The tile registers may be implemented as combined sets of vector registers.

One or more combined level 1 (L1 ) caches and shared memory units 873 store graphics data such as texture data, vertex data, pixel data, ray data, bounding volume data, etc., locally within each multi-core group 865A. One or more texture units 874 can also be used to perform texturing operations, such as texture mapping and sampling. A Level 2 (L2) cache 875 shared by all or a subset of the multi-core groups 865A-865N stores graphics data and/or instructions for multiple concurrent graphics threads. As illustrated, the L2 cache 875 may be shared across a plurality of multi-core groups 865A-865N. One or more memory controllers 867 couple the GPU 880 to a memory 866 which may be a system memory (e.g., DRAM) and/or a dedicated graphics memory (e.g., GDDR6 memory).

Input/output (I/O) circuitry 863 couples the GPU 880 to one or more I/O devices 862 such as digital signal processors (DSPs), network controllers, or user input devices. An on-chip interconnect may be used to couple the I/O devices 862 to the GPU 880 and memory 866. One or more I/O memory management units (IOMMUs) 864 of the I/O circuitry 863 couple the I/O devices 862 directly to the system memory 866. Optionally, the IOMMU 864 manages multiple sets of page tables to map virtual addresses to physical addresses in system memory 866. The I/O devices 862, CPU(s) 861, and GPU(s) 880 may then share the same virtual address space.

In one implementation of the IOMMU 864, the IOMMU 864 supports virtualization. In this case, it may manage a first set of page tables to map guest/graphics virtual addresses to guest/graphics physical addresses and a second set of page tables to map the guest/graphics physical addresses to system/host physical addresses (e.g., within system memory 866). The base addresses of each of the first and second sets of page tables may be stored in control registers and swapped out on a context switch (e.g., so that the new context is provided with access to the relevant set of page tables). While not illustrated in FIG. 8C, each of the cores 870, 871, 872 and/or multi-core groups 865A-865N may include translation lookaside buffers (TLBs) to cache guest virtual to guest physical translations, guest physical to host physical translations, and guest virtual to host physical translations.

The CPU(s) 861, GPUs 880, and I/O devices 862 may be integrated on a single semiconductor chip and/or chip package. The illustrated memory 866 may be integrated on the same chip or may be coupled to the memory controllers 867 via an off-chip interface. In one implementation, the memory 866 comprises GDDR6 memory which shares the same virtual address space as other physical system-level memories, although the underlying principles described herein are not limited to this specific implementation.

The tensor cores 871 may include a plurality of execution units specifically designed to perform matrix operations, which are the fundamental compute operation used to perform deep learning operations. For example, simultaneous matrix multiplication operations may be used for neural network training and inferencing. The tensor cores 871 may perform matrix processing using a variety of operand precisions including single precision floating-point (e.g., 32 bits), half-precision floating point (e.g., 16 bits), integer words (16 bits), bytes (8 bits), and half-bytes (4 bits). For example, a neural network implementation extracts features of each rendered scene, potentially combining details from multiple frames, to construct a high-quality final image.

In deep learning implementations, parallel matrix multiplication work may be scheduled for execution on the tensor cores 871. The training of neural networks, in particular, requires a significant number of matrix dot product operations. In order to process an inner-product formulation of an N×N×N matrix multiply, the tensor cores 871 may include at least N dot-product processing elements. Before the matrix multiply begins, one entire matrix is loaded into tile registers and at least one column of a second matrix is loaded each cycle for N cycles. Each cycle, there are N dot products that are processed.

Matrix elements may be stored at different precisions depending on the particular implementation, including 16-bit words, 8-bit bytes (e.g., INT8) and 4-bit half-bytes (e.g., INT4). Different precision modes may be specified for the tensor cores 871 to ensure that the most efficient precision is used for different workloads (e.g., such as inferencing workloads which can tolerate quantization to bytes and half-bytes). Supported formats additionally include 64-bit floating point (FP64) and non-IEEE floating point formats such as the bfloat16 format (e.g., Brain floating point), a 16-bit floating point format with one sign bit, eight exponent bits, and eight significand bits, of which seven are explicitly stored. One example includes support for a reduced precision tensor-float (TF32) mode, which performs computations using the range of FP32 (8-bits) and the precision of FP16 (10-bits). Reduced precision TF32 operations can be performed on FP32 inputs and produce FP32 outputs at higher performance relative to FP32 and increased precision relative to FP16. In some examples, one or more 8-bit floating point formats (FP8) are supported.

In some examples the tensor cores 871 support a sparse mode of operation for matrices in which the vast majority of values are zero. The tensor cores 871 include support for sparse input matrices that are encoded in a sparse matrix representation (e.g., coordinate list encoding (COO), compressed sparse row (CSR), compress sparse column (CSC), etc.). The tensor cores 871 also include support for compressed sparse matrix representations in the event that the sparse matrix representation may be further compressed. Compressed, encoded, and/or compressed and encoded matrix data, along with associated compression and/or encoding metadata, can be read by the tensor cores 871 and the non-zero values can be extracted. For example, for a given input matrix A, a non-zero value can be loaded from the compressed and/or encoded representation of at least a portion of matrix A. Based on the location in matrix A for the non-zero value, which may be determined from index or coordinate metadata associated with the non-zero value, a corresponding value in input matrix B may be loaded. Depending on the operation to be performed (e.g., multiply), the load of the value from input matrix B may be bypassed if the corresponding value is a zero value. In some examples, the pairings of values for certain operations, such as multiply operations, may be pre-scanned by scheduler logic and only operations between non-zero inputs are scheduled. Depending on the dimensions of matrix A and matrix B and the operation to be performed, output matrix C may be dense or sparse. Where output matrix C is sparse and depending on the configuration of the tensor cores 871, output matrix C may be output in a compressed format, a sparse encoding, or a compressed sparse encoding.

The ray tracing cores 872 may accelerate ray tracing operations for both real-time ray tracing and non-real-time ray tracing implementations. In particular, the ray tracing cores 872 may include ray traversal/intersection circuitry for performing ray traversal using bounding volume hierarchies (BVHs) and identifying intersections between rays and primitives enclosed within the BVH volumes. The ray tracing cores 872 may also include circuitry for performing depth testing and culling (e.g., using a Z buffer or similar arrangement). In one implementation, the ray tracing cores 872 perform traversal and intersection operations in concert with the image denoising techniques described herein, at least a portion of which may be executed on the tensor cores 871. For example, the tensor cores 871 may implement a deep learning neural network to perform denoising of frames generated by the ray tracing cores 872. However, the CPU(s) 861, graphics cores 870, and/or ray tracing cores 872 may also implement all or a portion of the denoising and/or deep learning algorithms.

In addition, as described above, a distributed approach to denoising may be employed in which the GPU 880 is in a computing device coupled to other computing devices over a network or high-speed interconnect. In this distributed approach, the interconnected computing devices may share neural network learning/training data to improve the speed with which the overall system learns to perform denoising for different types of image frames and/or different graphics applications.

The ray tracing cores 872 may process all BVH traversal and/or ray-primitive intersections, saving the graphics cores 870 from being overloaded with thousands of instructions per ray. For example, each ray tracing core 872 includes a first set of specialized circuitry for performing bounding box tests (e.g., for traversal operations) and/or a second set of specialized circuitry for performing the ray-triangle intersection tests (e.g., intersecting rays which have been traversed). Thus, for example, the multi-core group 865A can simply launch a ray probe, and the ray tracing cores 872 independently perform ray traversal and intersection and return hit data (e.g., a hit, no hit, multiple hits, etc.) to the thread context. The other cores 870, 871 are freed to perform other graphics or compute work while the ray tracing cores 872 perform the traversal and intersection operations.

Optionally, each ray tracing core 872 may include a traversal unit to perform BVH testing operations and/or an intersection unit which performs ray-primitive intersection tests. The intersection unit generates a “hit”, “no hit”, or “multiple hit” response, which it provides to the appropriate thread. During the traversal and intersection operations, the execution resources of the other cores (e.g., graphics cores 870 and tensor cores 871) are freed to perform other forms of graphics work.

In some examples described below, a hybrid rasterization/ray tracing approach is used in which work is distributed between the graphics cores 870 and ray tracing cores 872.

The ray tracing cores 872 (and/or other cores 870, 871) may include hardware support for a ray tracing instruction set such as Microsoft's DirectX Ray Tracing (DXR) which includes a DispatchRays command, as well as ray-generation, closest-hit, any-hit, and miss shaders, which enable the assignment of unique sets of shaders and textures for each object. Another ray tracing platform which may be supported by the ray tracing cores 872, graphics cores 870 and tensor cores 871 is Vulkan API (e.g., Vulkan version 1.1.85 and later). Note, however, that the underlying principles described herein are not limited to any particular ray tracing ISA.

In general, the various cores 872, 871, 870 may support a ray tracing instruction set that includes instructions/functions for one or more of ray generation, closest hit, any hit, ray-primitive intersection, per-primitive and hierarchical bounding box construction, miss, visit, and exceptions. More specifically, some examples includes ray tracing instructions to perform one or more of the following functions:
Ray Generation—Ray generation instructions may be executed for each pixel, sample, or other user-defined work assignment.
Closest Hit—A closest hit instruction may be executed to locate the closest intersection point of a ray with primitives within a scene.
Any Hit—An any hit instruction identifies multiple intersections between a ray and primitives within a scene, potentially to identify a new closest intersection point.
Intersection—An intersection instruction performs a ray-primitive intersection test and outputs a result.
Per-primitive Bounding box Construction—This instruction builds a bounding box around a given primitive or group of primitives (e.g., when building a new BVH or other acceleration data structure).
Miss—Indicates that a ray misses all geometry within a scene, or specified region of a scene.
Visit—Indicates the child volumes a ray will traverse.
Exceptions—Includes various types of exception handlers (e.g., invoked for various error conditions).

In some examples the ray tracing cores 872 may be adapted to accelerate general-purpose compute operations that can be accelerated using computational techniques that are analogous to ray intersection tests. A compute framework can be provided that enables shader programs to be compiled into low level instructions and/or primitives that perform general-purpose compute operations via the ray tracing cores. Exemplary computational problems that can benefit from compute operations performed on the ray tracing cores 872 include computations involving beam, wave, ray, or particle propagation within a coordinate space. Interactions associated with that propagation can be computed relative to a geometry or mesh within the coordinate space. For example, computations associated with electromagnetic signal propagation through an environment can be accelerated via the use of instructions or primitives that are executed via the ray tracing cores. Diffraction and reflection of the signals by objects in the environment can be computed as direct ray-tracing analogies.

Ray tracing cores 872 can also be used to perform computations that are not directly analogous to ray tracing. For example, mesh projection, mesh refinement, and volume sampling computations can be accelerated using the ray tracing cores 872. Generic coordinate space calculations, such as nearest neighbor calculations can also be performed. For example, the set of points near a given point can be discovered by defining a bounding box in the coordinate space around the point. BVH and ray probe logic within the ray tracing cores 872 can then be used to determine the set of point intersections within the bounding box. The intersections constitute the origin point and the nearest neighbors to that origin point. Computations that are performed using the ray tracing cores 872 can be performed in parallel with computations performed on the graphics cores 872 and tensor cores 871. A shader compiler can be configured to compile a compute shader or other general-purpose graphics processing program into low level primitives that can be parallelized across the graphics cores 870, tensor cores 871, and ray tracing cores 872.

Building larger and larger silicon dies is challenging for a variety of reasons. As silicon dies become larger, manufacturing yields become smaller and process technology requirements for different components may diverge. On the other hand, in order to have a high-performance system, key components should be interconnected by high speed, high bandwidth, low latency interfaces. These contradicting needs pose a challenge to high performance chip development.

Embodiments described herein provide techniques to disaggregate an architecture of a system on a chip integrated circuit into multiple distinct chiplets that can be packaged onto a common chassis. In some examples, a graphics processing unit or parallel processor is composed from diverse silicon chiplets that are separately manufactured. A chiplet is an at least partially packaged integrated circuit that includes distinct units of logic that can be assembled with other chiplets into a larger package. A diverse set of chiplets with different IP core logic can be assembled into a single device. Additionally the chiplets can be integrated into a base die or base chiplet using active interposer technology. The concepts described herein enable the interconnection and communication between the different forms of IP within the GPU. The development of IPs on different process may be mixed. This avoids the complexity of converging multiple IPs, especially on a large SoC with several flavors IPs, to the same process.

Enabling the use of multiple process technologies improves the time to market and provides a cost-effective way to create multiple product SKUs. For customers, this means getting products that are more tailored to their requirements in a cost effective and timely manner. Additionally, the disaggregated IPs are more amenable to being power gated independently, components that are not in use on a given workload can be powered off, reducing overall power consumption.

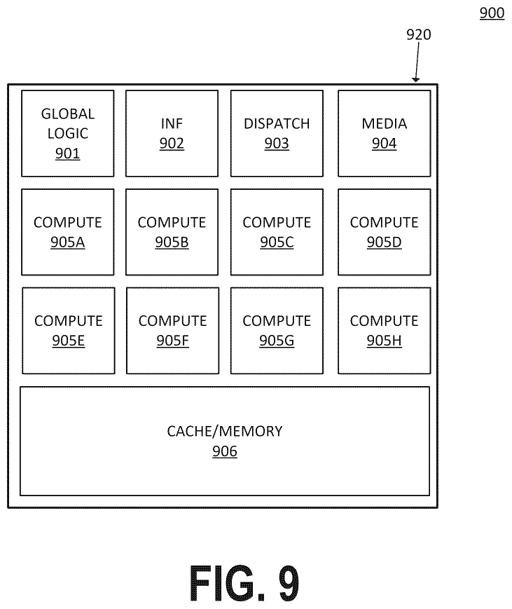

FIG. 9 shows a parallel compute system 900, according to some examples. In some examples the parallel compute system 900 includes a parallel processor 920, which can be a graphics processor or compute accelerator as described herein. The parallel processor 920 includes a global logic unit 901, an interface 902, a thread dispatcher 903, a media unit 904, a set of compute units 905A-905H, and a cache/memory units 906. The global logic unit 901, in some examples, includes global functionality for the parallel processor 920, including device configuration registers, global schedulers, power management logic, and the like. The interface 902 can include a front-end interface for the parallel processor 920. The thread dispatcher 903 can receive workloads from the interface 902 and dispatch threads for the workload to the compute units 905A-905H. If the workload includes any media operations, at least a portion of those operations can be performed by the media unit 904. The media unit can also offload some operations to the compute units 905A-905H. The cache/memory units 906 can include cache memory (e.g., L3 cache) and local memory (e.g., HBM, GDDR) for the parallel processor 920. Compute units 905 may include units for one or more of a network or communication processor, a core, a graphics processor, a general purpose graphics processing unit (GPGPU), a neural-network processing unit (NPU), an embedded processor, a security processor, a cryptographic accelerator, a matrix accelerator, an in-memory analytics accelerator, a compression accelerator, a data streaming accelerator, or the like.

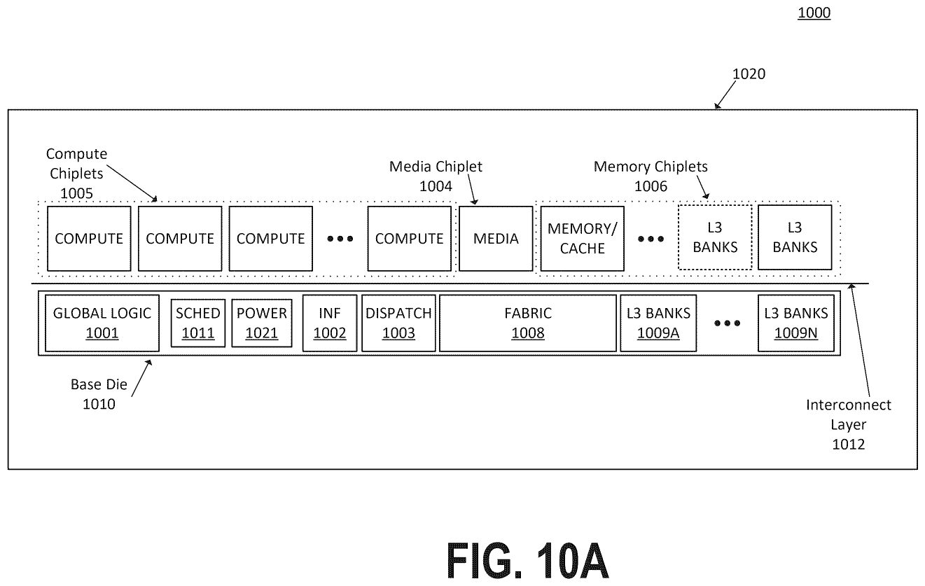

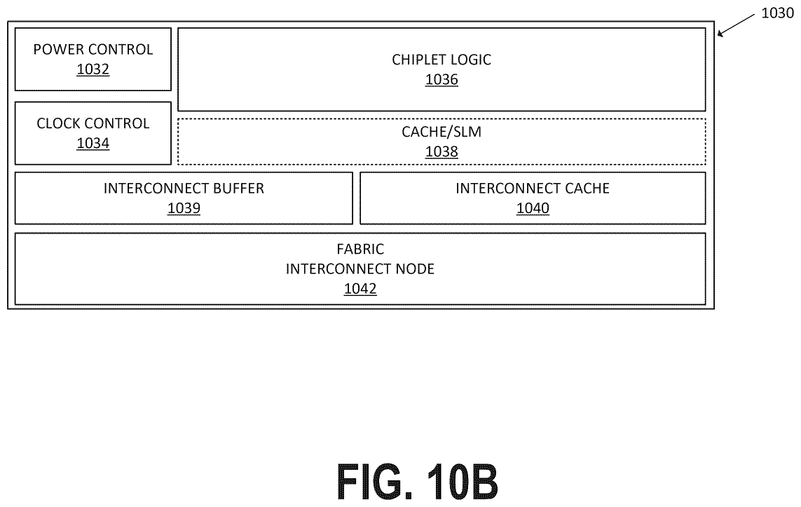

FIGS. 10A-10B illustrate a hybrid logical/physical view of a disaggregated parallel processor, according to examples described herein. FIG. 10A illustrates a disaggregated parallel compute system 1000. FIG. 10B illustrates a chiplet 1030 of the disaggregated parallel compute system 1000.

As shown in FIG. 10A, a disaggregated parallel compute system 1000 can include a parallel processor 1020 in which the various components of the parallel processor SOC are distributed across multiple chiplets. Each chiplet can be a distinct IP core that is independently designed and configured to communicate with other chiplets via one or more common interfaces. The chiplets include but are not limited to compute chiplets 1005, a media chiplet 1004, and memory chiplets 1006. Each chiplet can be separately manufactured using different process technologies. For example, compute chiplets 1005 may be manufactured using the smallest or most advanced process technology available at the time of fabrication, while memory chiplets 1006 or other chiplets (e.g., I/O, networking, etc.) may be manufactured using a larger or less advanced process technologies.

The various chiplets can be bonded to a base die 1010 and configured to communicate with each other and logic within the base die 1010 via an interconnect layer 1012. In some examples, the base die 1010 can include global logic 1001, which can include scheduler 1011 and power management 1021 logic units, an interface 1002, a dispatch unit 1003, and an interconnect fabric 1008 coupled with or integrated with one or more L3 cache banks 1009A-1009N. The interconnect fabric 1008 can be an inter-chiplet fabric that is integrated into the base die 1010. Logic chiplets can use the fabric 1008 to relay messages between the various chiplets. Additionally, L3 cache banks 1009A-1009N in the base die and/or L3 cache banks within the memory chiplets 1006 can cache data read from and transmitted to DRAM chiplets within the memory chiplets 1006 and to system memory of a host.

In some examples the global logic 1001 is a microcontroller that can execute firmware to perform scheduler 1011 and power management 1021 functionality for the parallel processor 1020. The microcontroller that executes the global logic can be tailored for the target use case of the parallel processor 1020. The scheduler 1011 can perform global scheduling operations for the parallel processor 1020. The power management 1021 functionality can be used to enable or disable individual chiplets within the parallel processor when those chiplets are not in use.

The various chiplets of the parallel processor 1020 can be designed to perform specific functionality that, in existing designs, would be integrated into a single die. A set of compute chiplets 1005 can include clusters of compute units (e.g., execution units, streaming multiprocessors, etc.) that include programmable logic to execute compute or graphics shader instructions. A media chiplet 1004 can include hardware logic to accelerate media encode and decode operations. Memory chiplets 1006 can include volatile memory (e.g., DRAM) and one or more SRAM cache memory banks (e.g., L3 banks).

As shown in FIG. 10B, each chiplet 1030 can include common components and application specific components. Chiplet logic 1036 within the chiplet 1030 can include the specific components of the chiplet, such as an array of streaming multiprocessors, compute units, or execution units described herein. The chiplet logic 1036 can couple with an optional cache or shared local memory 1038 or can include a cache or shared local memory within the chiplet logic 1036. The chiplet 1030 can include a fabric interconnect node 1042 that receives commands via the inter-chiplet fabric. Commands and data received via the fabric interconnect node 1042 can be stored temporarily within an interconnect buffer 1039. Data transmitted to and received from the fabric interconnect node 1042 can be stored in an interconnect cache 1040. Power control 1032 and clock control 1034 logic can also be included within the chiplet. The power control 1032 and clock control 1034 logic can receive configuration commands via the fabric can configure dynamic voltage and frequency scaling for the chiplet 1030. In some examples, each chiplet can have an independent clock domain and power domain and can be clock gated and power gated independently of other chiplets.

At least a portion of the components within the illustrated chiplet 1030 can also be included within logic embedded within the base die 1010 of FIG. 10A. For example, logic within the base die that communicates with the fabric can include a version of the fabric interconnect node 1042. Base die logic that can be independently clock or power gated can include a version of the power control 1032 and/or clock control 1034 logic.

Thus, while various examples described herein use the term SOC to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various examples of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).”

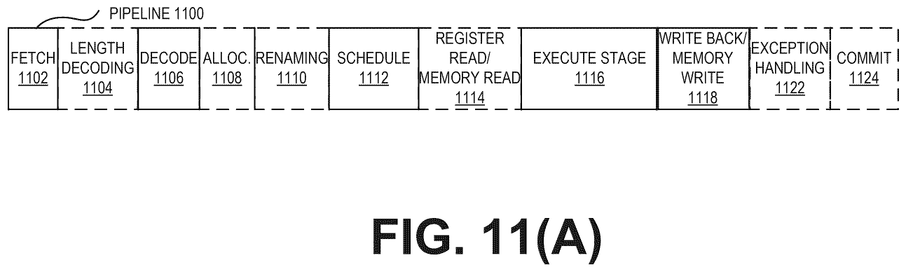

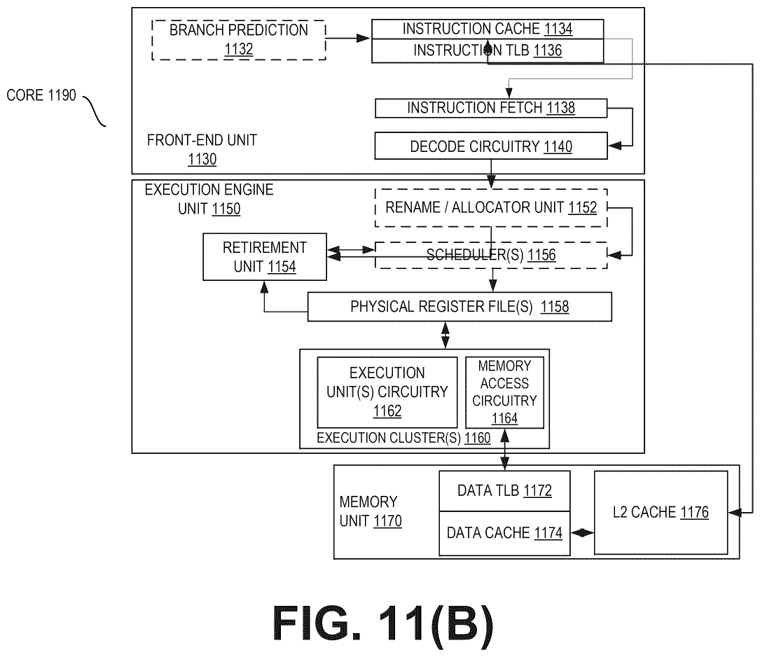

FIG. 11(A) is a block diagram illustrating both an example in-order pipeline and an example register renaming, out-of-order issue/execution pipeline according to examples. FIG. 11(B) is a block diagram illustrating both an example in-order architecture core and an example register renaming, out-of-order issue/execution architecture core to be included in a processor according to examples. The solid lined boxes in FIG. 11(A)-(B) illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 11(A), a processor pipeline 1100 includes a fetch stage 1102, an optional length decoding stage 1104, a decode stage 1106, an optional allocation (Alloc) stage 1108, an optional renaming stage 1110, a schedule (also known as a dispatch or issue) stage 1112, an optional register read/memory read stage 1114, an execute stage 1116, a write back/memory write stage 1118, an optional exception handling stage 1122, and an optional commit stage 1124. One or more operations can be performed in each of these processor pipeline stages. For example, during the fetch stage 1102, one or more instructions are fetched from instruction memory, and during the decode stage 1106, the one or more fetched instructions may be decoded, addresses (e.g., load store unit (LSU) addresses) using forwarded register ports may be generated, and branch forwarding (e.g., immediate offset or a link register (LR)) may be performed. In some examples, the decode stage 1106 and the register read/memory read stage 1114 may be combined into one pipeline stage. In some examples, during the execute stage 1116, the decoded instructions may be executed, LSU address/data pipelining to an Advanced Microcontroller Bus (AMB) interface may be performed, multiply and add operations may be performed, arithmetic operations with branch results may be performed, etc.

By way of example, the example register renaming, out-of-order issue/execution architecture core of FIG. 11(B) may implement the pipeline 1100 as follows: 1) the instruction fetch circuitry 1138 performs the fetch and length decoding stages 1102 and 1104; 2) the decode circuitry 1140 performs the decode stage 1106; 3) the rename/allocator unit circuitry 1152 performs the allocation stage 1108 and renaming stage 1110; 4) the scheduler(s) circuitry 1156 performs the schedule stage 1112; 5) the physical register file(s) circuitry 1158 and the memory unit circuitry 1170 perform the register read/memory read stage 1114; the execution cluster(s) 1160 perform the execute stage 1116; 6) the memory unit circuitry 1170 and the physical register file(s) circuitry 1158 perform the write back/memory write stage 1118; 7) various circuitry may be involved in the exception handling stage 1122; and 8) the retirement unit circuitry 1154 and the physical register file(s) circuitry 1158 perform the commit stage 1124.

FIG. 11(B) shows a processor core 1190 including front-end unit circuitry 1130 coupled to execution engine unit circuitry 1150, and both are coupled to memory unit circuitry 1170. The core 1190 may be a reduced instruction set architecture computing (RISC) core, a complex instruction set architecture computing (CISC) core, a very long instruction word (VLIW) core, or a hybrid or alternative core type. As yet another option, the core 1190 may be a special-purpose core, such as, for example, a network or communication core, compression engine, co-processor core, general purpose computing graphics processing unit (GPGPU) core, graphics core, or the like.

The front-end unit circuitry 1130 may include branch prediction circuitry 1132 coupled to instruction cache circuitry 1134, which is coupled to an instruction translation lookaside buffer (TLB) 1136, which is coupled to instruction fetch circuitry 1138, which is coupled to decode circuitry 1140. In some examples, the instruction cache circuitry 1134 is included in the memory unit circuitry 1170 rather than the front-end unit circuitry 1130. The decode circuitry 1140 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 1140 may further include address generation unit (AGU, not shown) circuitry. In some examples, the AGU generates an LSU address using forwarded register ports, and may further perform branch forwarding (e.g., immediate offset branch forwarding, LR register branch forwarding, etc.). The decode circuitry 1140 may be implemented using various different mechanisms. Examples of suitable mechanisms include, but are not limited to, look-up tables, hardware implementations, programmable logic arrays (PLAs), microcode read only memories (ROMs), etc. In some examples, the core 1190 includes a microcode ROM (not shown) or other medium that stores microcode for certain macroinstructions (e.g., in decode circuitry 1140 or otherwise within the front-end unit circuitry 1130). In some examples, the decode circuitry 1140 includes a micro-operation (micro-op) or operation cache (not shown) to hold/cache decoded operations, micro-tags, or micro-operations generated during the decode or other stages of the processor pipeline 1100. The decode circuitry 1140 may be coupled to rename/allocator unit circuitry 1152 in the execution engine unit circuitry 1150.

The execution engine unit circuitry 1150 includes the rename/allocator unit circuitry 1152 coupled to retirement unit circuitry 1154 and a set of one or more scheduler(s) circuitry 1156. The scheduler(s) circuitry 1156 represents any number of different schedulers, including reservations stations, central instruction window, etc. In some examples, the scheduler(s) circuitry 1156 can include arithmetic logic unit (ALU) scheduler/scheduling circuitry, ALU queues, address generation unit (AGU) scheduler/scheduling circuitry, AGU queues, etc. The scheduler(s) circuitry 1156 is coupled to the physical register file(s) circuitry 1158. Each of the physical register file(s) circuitry 1158 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In some examples, the physical register file(s) circuitry 1158 includes vector registers unit circuitry, writemask registers unit circuitry, and scalar register unit circuitry. These register units may provide architectural vector registers, vector mask registers, general-purpose registers, etc. The physical register file(s) circuitry 1158 is coupled to the retirement unit circuitry 1154 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 1154 and the physical register file(s) circuitry 1158 are coupled to the execution cluster(s) 1160. The execution cluster(s) 1160 includes a set of one or more execution unit(s) circuitry 1162 and a set of one or more memory access circuitry 1164. The execution unit(s) circuitry 1162 may perform various arithmetic, logic, floating-point or other types of operations (e.g., shifts, addition, subtraction, multiplication) and on various types of data (e.g., scalar integer, scalar floating-point, packed integer, packed floating-point, vector integer, vector floating-point). In some examples, execution unit(s) circuitry 1162 may include hardware to support functionality for instructions for one or more of a compression engine, graphics processing, neural-network processing, in-memory analytics, matrix operations, cryptographic operations, data streaming operations, data graph operations, etc.

While some examples may include a number of execution units or execution unit circuitry dedicated to specific functions or sets of functions, other examples may include only one execution unit circuitry or multiple execution units/execution unit circuitry that all perform all functions. The scheduler(s) circuitry 1156, physical register file(s) circuitry 1158, and execution cluster(s) 1160 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) circuitry, and/or execution cluster - and in the case of a separate memory access pipeline, certain examples are implemented in which only the execution cluster of this pipeline has the memory access unit(s) circuitry 1164). It should also be understood that where separate pipelines are used, one or more of these pipelines may be out-of-order issue/execution and the rest in-order.

In some examples, the execution engine unit circuitry 1150 may perform load store unit (LSU) address/data pipelining to an Advanced Microcontroller Bus (AMB) interface (not shown), and address phase and writeback, data phase load, store, and branches.

The set of memory access circuitry 1164 is coupled to the memory unit circuitry 1170, which includes data TLB circuitry 1172 coupled to data cache circuitry 1174 coupled to level 2 (L2) cache circuitry 1176. In some examples, the memory access circuitry 1164 may include load unit circuitry, store address unit circuitry, and store data unit circuitry, each of which is coupled to the data TLB circuitry 1172 in the memory unit circuitry 1170. The instruction cache circuitry 1134 is further coupled to the level 2 (L2) cache circuitry 1176 in the memory unit circuitry 1170. In some examples, the instruction cache 1134 and the data cache 1174 are combined into a single instruction and data cache (not shown) in L2 cache circuitry 1176, level 3 (L3) cache circuitry (not shown), and/or main memory. The L2 cache circuitry 1176 is coupled to one or more other levels of cache and eventually to a main memory.

The core 1190 may support one or more instructions sets (e.g., the x86 instruction set architecture (optionally with some extensions that have been added with newer versions); the MIPS instruction set architecture; the ARM instruction set architecture (optionally with optional additional extensions such as NEON, etc.); RISC instruction set architecture), including the instruction(s) described herein. In some examples, the core 1190 includes logic to support a packed data instruction set architecture extension (e.g., AVX1, AVX2, AVX512, AMX, etc.), thereby allowing the operations used by many multimedia applications to be performed using packed data.

### Example Execution Unit(s) Circuitry.

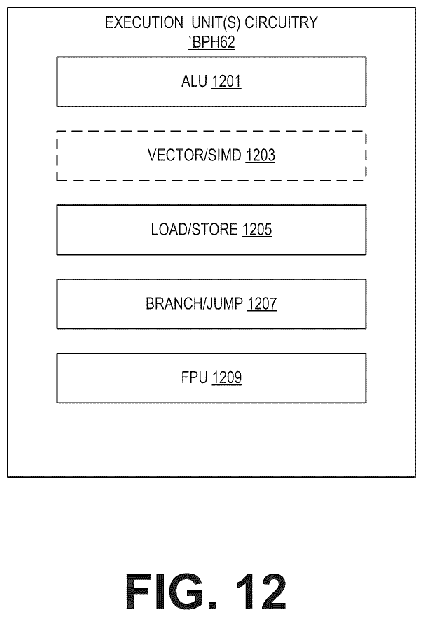

FIG. 12 illustrates examples of execution unit(s) circuitry, such as execution unit(s) circuitry 1162 of FIG. 11(B). As illustrated, execution unit(s) circuitry 1162 may include one or more ALU circuits 1201, optional vector/single instruction multiple data (SIMD) circuits 1203, load/store circuits 1205, branch/jump circuits 1207, and/or Floating-point unit (FPU) circuits 1209. ALU circuits 1201 perform integer arithmetic and/or Boolean operations. Vector/SIMD circuits 1203 perform vector/SIMD operations on packed data (such as SIMD/vector registers). Load/store circuits 1205 execute load and store instructions to load data from memory into registers or store from registers to memory. Load/store circuits 1205 may also generate addresses. Branch/jump circuits 1207 cause a branch or jump to a memory address depending on the instruction. FPU circuits 1209 perform floating-point arithmetic. The width of the execution unit(s) circuitry 1162 varies depending upon the example and can range from 16-bit to 1,024-bit, for example. In some examples, two or more smaller execution units are logically combined to form a larger execution unit (e.g., two 128-bit execution units are logically combined to form a 256-bit execution unit).

### Example Register Architecture.

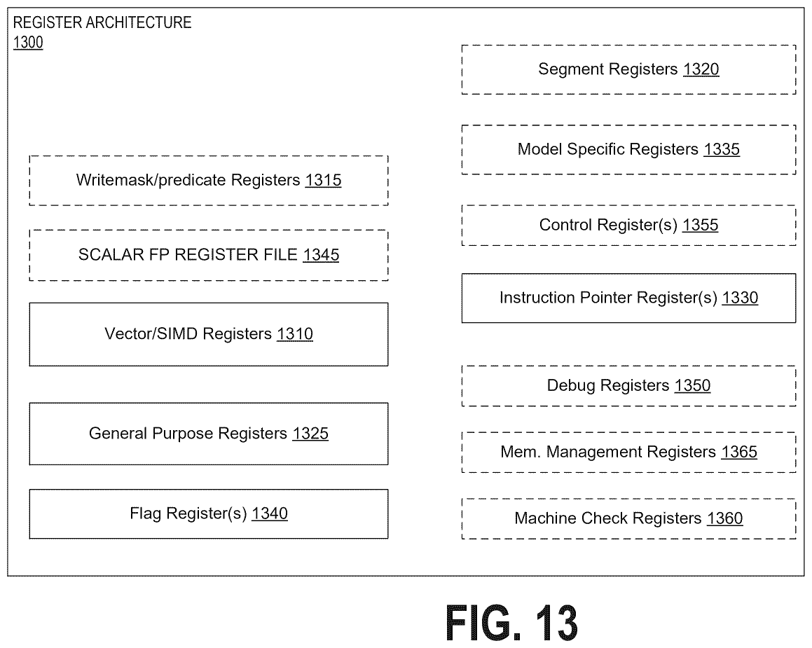

FIG. 13 is a block diagram of a register architecture 1300 according to some examples. As illustrated, the register architecture 1300 includes vector/SIMD registers 1310 that vary from 128-bit to 1,024 bits width. In some examples, the vector/SIMD registers 1310 are physically 512-bits and, depending upon the mapping, only some of the lower bits are used. For example, in some examples, the vector/SIMD registers 1310 are ZMM registers which are 512 bits: the lower 256 bits are used for YMM registers and the lower 128 bits are used for XMM registers. As such, there is an overlay of registers. In some examples, a vector length field selects between a maximum length and one or more other shorter lengths, where each such shorter length is half the length of the preceding length. Scalar operations are operations performed on the lowest order data element position in a ZMM/YMM/XMM register; the higher order data element positions are either left the same as they were prior to the instruction or zeroed depending on the example.

In some examples, the register architecture 1300 includes writemask/predicate registers 1315. For example, in some examples, there are 8 writemask/predicate registers (sometimes called k0 through k7) that are each 16-bit, 32-bit, 64-bit, or 128-bit in size. Writemask/predicate registers 1315 may allow for merging (e.g., allowing any set of elements in the destination to be protected from updates during the execution of any operation) and/or zeroing (e.g., zeroing vector masks allow any set of elements in the destination to be zeroed during the execution of any operation). In some examples, each data element position in a given writemask/predicate register 1315 corresponds to a data element position of the destination. In other examples, the writemask/predicate registers 1315 are scalable and consists of a set number of enable bits for a given vector element (e.g., 8 enable bits per 64-bit vector element).

The register architecture 1300 includes a plurality of general-purpose registers 1325. These registers may be 16-bit, 32-bit, 64-bit, etc. and can be used for scalar operations. In some examples, these registers are referenced by the names RAX, RBX, RCX, RDX, RBP, RSI, RDI, RSP, and R8 through R15.

In some examples, the register architecture 1300 includes scalar floating-point (FP) register file 1345 which is used for scalar floating-point operations on 32/64/80-bit floating-point data using the x87 instruction set architecture extension or as MMX registers to perform operations on 64-bit packed integer data, as well as to hold operands for some operations performed between the MMX and XMM registers.

One or more flag registers 1340 (e.g., EFLAGS, RFLAGS, etc.) store status and control information for arithmetic, compare, and system operations. For example, the one or more flag registers 1340 may store condition code information such as carry, parity, auxiliary carry, zero, sign, and overflow. In some examples, the one or more flag registers 1340 are called program status and control registers.

Segment registers 1320 contain segment points for use in accessing memory. In some examples, these registers are referenced by the names CS, DS, SS, ES, FS, and GS.

Model specific registers or machine specific registers (MSRs) 1335 control and report on processor performance. Most MSRs 1335 handle system-related functions and are not accessible to an application program. For example, MSRs may provide control for one or more of: performance-monitoring counters, debug extensions, memory type range registers, thermal and power management, instruction-specific support, and/or processor feature/mode support. Machine check registers 1360 consist of control, status, and error reporting MSRs that are used to detect and report on hardware errors. Control register(s) 1355 (e.g., CR0-CR4) determine the operating mode of a processor (e.g., processor 470, 480, 438, 415, and/or 500) and the characteristics of a currently executing task. In some examples, MSRs 1335 are a subset of control registers 1355.

One or more instruction pointer register(s) 1330 store an instruction pointer value. Debug registers 1350 control and allow for the monitoring of a processor or core's debugging operations.

Memory (mem) management registers 1365 specify the locations of data structures used in protected mode memory management. These registers may include a global descriptor table register (GDTR), interrupt descriptor table register (IDTR), task register, and a local descriptor table register (LDTR) register.

Alternative examples may use wider or narrower registers. Additionally, alternative examples may use more, less, or different register files and registers. The register architecture 1300 may, for example, be used in register file/memory ‘ISAB08, or physical register file(s) circuitry 11 58.

### Instruction Set Architectures.

An instruction set architecture (ISA) may include one or more instruction formats. A given instruction format may define various fields (e.g., number of bits, location of bits) to specify, among other things, the operation to be performed (e.g., opcode) and the operand(s) on which that operation is to be performed and/or other data field(s) (e.g., mask). Some instruction formats are further broken down through the definition of instruction templates (or sub-formats). For example, the instruction templates of a given instruction format may be defined to have different subsets of the instruction format's fields (the included fields are typically in the same order, but at least some have different bit positions because there are less fields included) and/or defined to have a given field interpreted differently. Thus, each instruction of an ISA is expressed using a given instruction format (and, if defined, in a given one of the instruction templates of that instruction format) and includes fields for specifying the operation and the operands. For example, an example ADD instruction has a specific opcode and an instruction format that includes an opcode field to specify that opcode and operand fields to select operands (source1/destination and source2); and an occurrence of this ADD instruction in an instruction stream will have specific contents in the operand fields that select specific operands. In addition, though the description below is made in the context of x86 ISA, it is within the knowledge of one skilled in the art to apply the teachings of the present disclosure in another ISA.

### Example Instruction Formats.

Examples of the instruction(s) described herein may be embodied in different formats. Additionally, example systems, architectures, and pipelines are detailed below. Examples of the instruction(s) may be executed on such systems, architectures, and pipelines, but are not limited to those detailed.

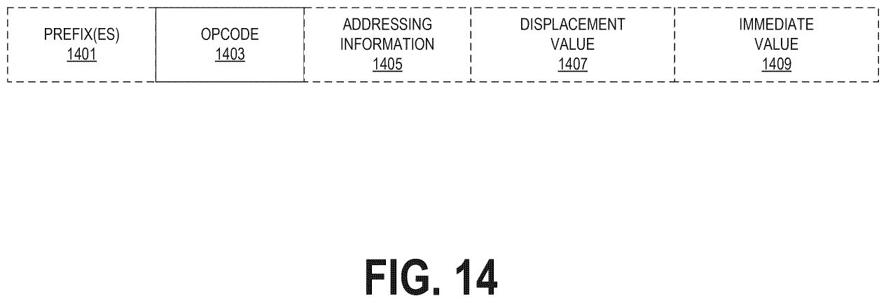

FIG. 14 illustrates examples of an instruction format. As illustrated, an instruction may include multiple components including, but not limited to, one or more fields for: one or more prefixes, an opcode, addressing information (e.g., register identifiers, memory addressing information, etc.), a displacement value, and/or an immediate value. Note that some instructions utilize some or all the fields of the format whereas others may only use the field for the opcode 1403. In some examples, the order illustrated is the order in which these fields are to be encoded, however, it should be appreciated that in other examples these fields may be encoded in a different order, combined, etc.

The prefix(es) f 1401, when used, modifies an instruction. In some examples, one or more prefixes are used to repeat string instructions (e.g., 0xF0, 0xF 2, 0xF 3, etc.), to provide section overrides (e.g., 0x2E, 0x36, 0x3E, 0x26, 0x64, 0x65, 0x2E, 0x3E, etc.), to perform bus lock operations, and/or to change operand (e.g., 0x66) and address sizes (e.g., 0x67). Certain instructions require a mandatory prefix (e.g., 0x66, 0xF2, 0xF3, etc.). Certain of these prefixes may be considered “legacy” prefixes. Other prefixes, one or more examples of which are detailed herein, indicate, and/or provide further capability, such as specifying particular registers, etc. The other prefixes typically follow the “legacy” prefixes.

The opcode field 1403 is used to at least partially define the operation to be performed upon a decoding of the instruction. In some examples, a primary opcode encoded in the opcode field 1403 is one, two, or three bytes in length. In other examples, a primary opcode can be a different length. An additional 3-bit opcode field is sometimes encoded in another field. The addressing information field 1405 is used to address one or more operands of the instruction, such as a location in memory or one or more registers.

### Graphics Execution Units

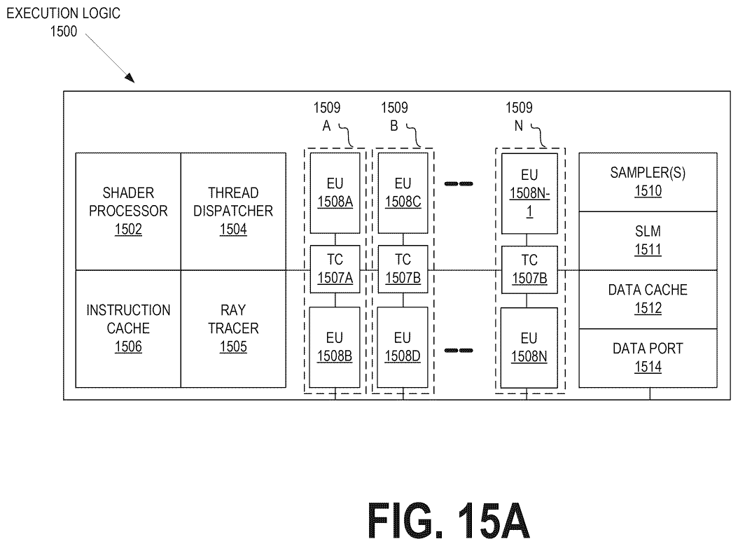

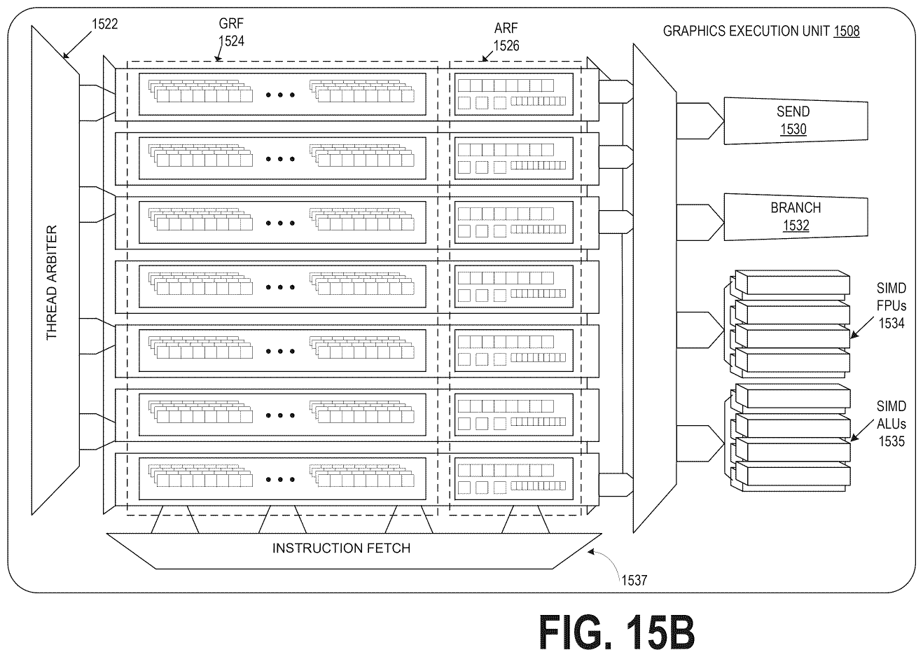

FIGS. 15A-15B illustrate thread execution logic 1500 including an array of processing elements employed in a graphics processor core according to examples described herein. Elements of FIGS. 15A-15B having the same reference numbers (or names) as the elements of any other figure herein can operate or function in any manner similar to that described elsewhere herein, but are not limited to such. FIG. 15A is representative of an execution unit within a general-purpose graphics processor, while FIG. 15B is representative of an execution unit that may be used within a compute accelerator.

As illustrated in FIG. 15A, in some examples thread execution logic 1500 includes a shader processor 1502, a thread dispatcher 1504, instruction cache 1506, a scalable execution unit array including a plurality of execution units 1508A-1508N, a sampler 1510, shared local memory 1511, a data cache 1512, and a data port 1514. In some examples the scalable execution unit array can dynamically scale by enabling or disabling one or more execution units (e.g., any of execution units 1508A, 1508B, 1508C, 1508D, through 1508N-1 and 1508N) based on the computational requirements of a workload. In some examples the included components are interconnected via an interconnect fabric that links to each of the components. In some examples, thread execution logic 1500 includes one or more connections to memory, such as system memory or cache memory, through one or more of instruction cache 1506, data port 1514, sampler 1510, and execution units 1508A-1508N. In some examples, each execution unit (e.g. 1508A) is a stand-alone programmable general-purpose computational unit that is capable of executing multiple simultaneous hardware threads while processing multiple data elements in parallel for each thread. In various examples, the array of execution units 1508A-1508N is scalable to include any number individual execution units.

In some examples, the execution units 1508A-1508N are primarily used to execute shader programs. A shader processor 1502 can process the various shader programs and dispatch execution threads associated with the shader programs via a thread dispatcher 1504. In some examples the thread dispatcher includes logic to arbitrate thread initiation requests from the graphics and media pipelines and instantiate the requested threads on one or more execution unit in the execution units 1508A-1508N. For example, a geometry pipeline can dispatch vertex, tessellation, or geometry shaders to the thread execution logic for processing. In some examples, thread dispatcher 1504 can also process runtime thread spawning requests from the executing shader programs.

In some examples, the execution units 1508A-1508N support an instruction set that includes native support for many standard 3D graphics shader instructions, such that shader programs from graphics libraries (e.g., Direct 3D and OpenGL) are executed with a minimal translation. The execution units support vertex and geometry processing (e.g., vertex programs, geometry programs, vertex shaders), pixel processing (e.g., pixel shaders, fragment shaders) and general-purpose processing (e.g., compute and media shaders). Each of the execution units 1508A-1508N is capable of multi-issue single instruction multiple data (SIMD) execution and multi-threaded operation enables an efficient execution environment in the face of higher latency memory accesses. Each hardware thread within each execution unit has a dedicated high-bandwidth register file and associated independent thread-state. Execution is multi-issue per clock to pipelines capable of integer, single and double precision floating point operations, SIMD branch capability, logical operations, transcendental operations, and other miscellaneous operations. While waiting for data from memory or one of the shared functions, dependency logic within the execution units 1508A-1508N causes a waiting thread to sleep until the requested data has been returned. While the waiting thread is sleeping, hardware resources may be devoted to processing other threads. For example, during a delay associated with a vertex shader operation, an execution unit can perform operations for a pixel shader, fragment shader, or another type of shader program, including a different vertex shader. Various examples can apply to use execution by use of Single Instruction Multiple Thread (SIMT) as an alternate to use of SIMD or in addition to use of SIMD. Reference to a SIMD core or operation can apply also to SIMT or apply to SIMD in combination with SIMT.

Each execution unit in execution units 1508A-1508N operates on arrays of data elements. The number of data elements is the “execution size,” or the number of channels for the instruction. An execution channel is a logical unit of execution for data element access, masking, and flow control within instructions. The number of channels may be independent of the number of physical Arithmetic Logic Units (ALUs) or Floating Point Units (FPUs) for a particular graphics processor. In some examples, execution units 1508A-1508N support integer and floating-point data types.

The execution unit instruction set includes SIMD instructions. The various data elements can be stored as a packed data type in a register and the execution unit will process the various elements based on the data size of the elements. For example, when operating on a 256-bit wide vector, the 256 bits of the vector are stored in a register and the execution unit operates on the vector as four separate 64-bit packed data elements (Quad-Word (QW) size data elements), eight separate 32-bit packed data elements (Double Word (DW) size data elements), sixteen separate 16-bit packed data elements (Word (W) size data elements), or thirty-two separate 8-bit data elements (byte (B) size data elements). However, different vector widths and register sizes are possible.

In some examples one or more execution units can be combined into a fused graphics execution unit 1509A-1509N having thread control logic (1507A-1507N) that is common to the fused EUs. Multiple EUs can be fused into an EU group. Each EU in the fused EU group can be configured to execute a separate SIMD hardware thread. The number of EUs in a fused EU group can vary according to examples. Additionally, various SIMD widths can be performed per-EU, including but not limited to SIMD8, SIMD16, and SIMD32. Each fused graphics execution unit 1509A-1509N includes at least two execution units. For example, fused execution unit 1509A includes a first EU 1508A, second EU 1508B, and thread control logic 1507A that is common to the first EU 1508A and the second EU 1508B. The thread control logic 1507A controls threads executed on the fused graphics execution unit 1509A, allowing each EU within the fused execution units 1509A-1509N to execute using a common instruction pointer register.

One or more internal instruction caches (e.g., 1506) are included in the thread execution logic 1500 to cache thread instructions for the execution units. In some examples, one or more data caches (e.g., 1512) are included to cache thread data during thread execution. Threads executing on the thread execution logic 1500 can also store explicitly managed data in the shared local memory 1511. In some examples, a sampler 1510 is included to provide texture sampling for 3D operations and media sampling for media operations. In some examples, sampler 1510 includes specialized texture or media sampling functionality to process texture or media data during the sampling process before providing the sampled data to an execution unit.

During execution, the graphics and media pipelines send thread initiation requests to thread execution logic 1500 via thread spawning and dispatch logic. Once a group of geometric objects has been processed and rasterized into pixel data, pixel processor logic (e.g., pixel shader logic, fragment shader logic, etc.) within the shader processor 1502 is invoked to further compute output information and cause results to be written to output surfaces (e.g., color buffers, depth buffers, stencil buffers, etc.). In some examples, a pixel shader or fragment shader calculates the values of the various vertex attributes that are to be interpolated across the rasterized object. In some examples, pixel processor logic within the shader processor 1502 then executes an application programming interface (API)-supplied pixel or fragment shader program. To execute the shader program, the shader processor 1502 dispatches threads to an execution unit (e.g., 1508A) via thread dispatcher 1504. In some examples, shader processor 1502 uses texture sampling logic in the sampler 1510 to access texture data in texture maps stored in memory. Arithmetic operations on the texture data and the input geometry data compute pixel color data for each geometric fragment, or discards one or more pixels from further processing.

In some examples, the data port 1514 provides a memory access mechanism for the thread execution logic 1500 to output processed data to memory for further processing on a graphics processor output pipeline. In some examples, the data port 1514 includes or couples to one or more cache memories (e.g., data cache 1512) to cache data for memory access via the data port.

In some examples, the execution logic 1500 can also include a ray tracer 1505 that can provide ray tracing acceleration functionality. The ray tracer 1505 can support a ray tracing instruction set that includes instructions/functions for ray generation.

FIG. 15B illustrates exemplary internal details of an execution unit 1508, according to examples. A graphics execution unit 1508 can include an instruction fetch unit 1537, a general register file array (GRF) 1524, an architectural register file array (ARF) 1526, a thread arbiter 1522, a send unit 1530, a branch unit 1532, a set of SIMD floating point units (FPUs) 1534, and in some examples a set of dedicated integer SIMD ALUs 1535. The GRF 1524 and ARF 1526 includes the set of general register files and architecture register files associated with each simultaneous hardware thread that may be active in the graphics execution unit 1508. In some examples, per thread architectural state is maintained in the ARF 1526, while data used during thread execution is stored in the GRF 1524. The execution state of each thread, including the instruction pointers for each thread, can be held in thread-specific registers in the ARF 1526.

In some examples the graphics execution unit 1508 has an architecture that is a combination of Simultaneous Multi-Threading (SMT) and fine-grained Interleaved Multi-Threading (IMT). The architecture has a modular configuration that can be fine-tuned at design time based on a target number of simultaneous threads and number of registers per execution unit, where execution unit resources are divided across logic used to execute multiple simultaneous threads. The number of logical threads that may be executed by the graphics execution unit 1508 is not limited to the number of hardware threads, and multiple logical threads can be assigned to each hardware thread.

In some examples, the graphics execution unit 1508 can co-issue multiple instructions, which may each be different instructions. The thread arbiter 1522 of the graphics execution unit thread 1508 can dispatch the instructions to one of the send unit 1530, branch unit 1532, or SIMD FPU(s) 1534 for execution. Each execution thread can access 128 general-purpose registers within the GRF 1524, where each register can store 32 bytes, accessible as a SIMD 8-element vector of 32-bit data elements. In some examples, each execution unit thread has access to 4 Kbytes within the GRF 1524, although examples are not so limited, and greater or fewer register resources may be provided in other examples. In some examples the graphics execution unit 1508 is partitioned into seven hardware threads that can independently perform computational operations, although the number of threads per execution unit can also vary according to examples. For example, in some examples up to 16 hardware threads are supported. In an example in which seven threads may access 4 Kbytes, the GRF 1524 can store a total of 28 Kbytes. Where 16 threads may access 4 Kbytes, the GRF 1524 can store a total of 64 Kbytes. Flexible addressing modes can permit registers to be addressed together to build effectively wider registers or to represent strided rectangular block data structures.

In some examples, memory operations, sampler operations, and other longer-latency system communications are dispatched via “send” instructions that are executed by the message passing send unit 1530. In some examples, branch instructions are dispatched to a dedicated branch unit 1532 to facilitate SIMD divergence and eventual convergence.

In some examples the graphics execution unit 1508 includes one or more SIMD FPU(s) 1534 to perform floating-point operations. In some examples, the FPU(s) 1534 also support integer computation. In some examples the FPU(s) 1534 can SIMD execute up to M number of 32-bit floating-point (or integer) operations, or SIMD execute up to 2 M 16-bit integer or 16-bit floating-point operations. In some examples, at least one of the FPU(s) provides extended math capability to support high-throughput transcendental math functions and double precision 64-bit floating-point. In some examples, a set of 8-bit integer SIMD ALUs 1535 are also present, and may be specifically optimized to perform operations associated with machine learning computations.

In some examples, arrays of multiple instances of the graphics execution unit 1508 can be instantiated in a graphics sub-core grouping (e.g., a sub-slice). For scalability, product architects can choose the exact number of execution units per sub-core grouping. In some examples the execution unit 1508 can execute instructions across a plurality of execution channels. In a further example, each thread executed on the graphics execution unit 1508 is executed on a different channel.

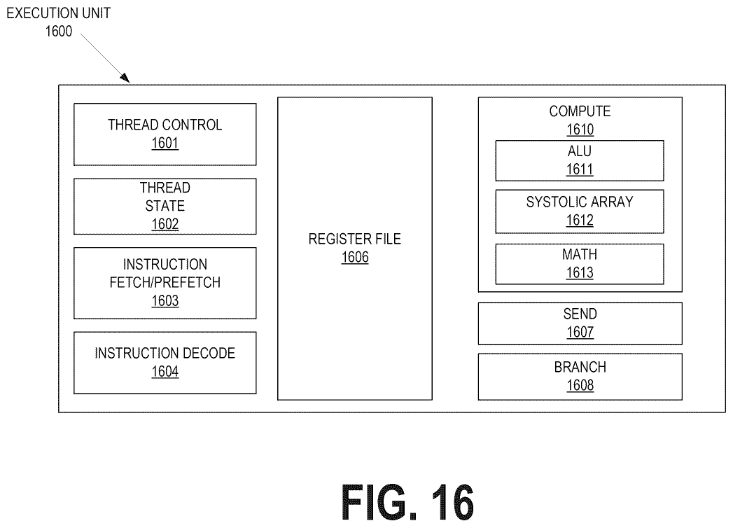

FIG. 16 illustrates an additional execution unit 1600, according to an example. In some examples, the execution unit 1600 includes a thread control unit 1601, a thread state unit 1602, an instruction fetch/prefetch unit 1603, and an instruction decode unit 1604. The execution unit 1600 additionally includes a register file 1606 that stores registers that can be assigned to hardware threads within the execution unit. The execution unit 1600 additionally includes a send unit 1607 and a branch unit 1608. In some examples, the send unit 1607 and branch unit 1608 can operate similarly as the send unit 1530 and a branch unit 1532 of the graphics execution unit 1508 of FIG. 15B.

The execution unit 1600 also includes a compute unit 1610 that includes multiple different types of functional units. In some examples the compute unit 1610 includes an ALU unit 1611 that includes an array of arithmetic logic units. The ALU unit 1611 can be configured to perform 64-bit, 32-bit, and 16-bit integer and floating point operations. Integer and floating point operations may be performed simultaneously. The compute unit 1610 can also include a systolic array 1612, and a math unit 1613. The systolic array 1612 includes a W wide and D deep network of data processing units that can be used to perform vector or other data-parallel operations in a systolic manner. In some examples the systolic array 1612 can be configured to perform matrix operations, such as matrix dot product operations. In some examples the systolic array 1612 support 16-bit floating point operations, as well as 8-bit and 4-bit integer operations. In some examples the systolic array 1612 can be configured to accelerate machine learning operations. In such examples, the systolic array 1612 can be configured with support for the bfloat 16-bit floating point format. In some examples, a math unit 1613 can be included to perform a specific subset of mathematical operations in an efficient and lower-power manner than the ALU unit 1611. The math unit 1613 can include a variant of math logic that may be found in shared function logic of a graphics processing engine provided by other examples. In some examples the math unit 1613 can be configured to perform 32-bit and 64-bit floating point operations.

The thread control unit 1601 includes logic to control the execution of threads within the execution unit. The thread control unit 1601 can include thread arbitration logic to start, stop, and preempt execution of threads within the execution unit 1600. The thread state unit 1602 can be used to store thread state for threads assigned to execute on the execution unit 1600. Storing the thread state within the execution unit 1600 enables the rapid pre-emption of threads when those threads become blocked or idle. The instruction fetch/prefetch unit 1603 can fetch instructions from an instruction cache of higher level execution logic (e.g., instruction cache 1506 as in FIG. 15A). The instruction fetch/prefetch unit 1603 can also issue prefetch requests for instructions to be loaded into the instruction cache based on an analysis of currently executing threads. The instruction decode unit 1604 can be used to decode instructions to be executed by the compute units. In some examples, the instruction decode unit 1604 can be used as a secondary decoder to decode complex instructions into constituent micro-operations.

The execution unit 1600 additionally includes a register file 1606 that can be used by hardware threads executing on the execution unit 1600. Registers in the register file 1606 can be divided across the logic used to execute multiple simultaneous threads within the compute unit 1610 of the execution unit 1600. The number of logical threads that may be executed by the execution unit 1600 is not limited to the number of hardware threads, and multiple logical threads can be assigned to each hardware thread. The size of the register file 1606 can vary across examples based on the number of supported hardware threads. In some examples, register renaming may be used to dynamically allocate registers to hardware threads.

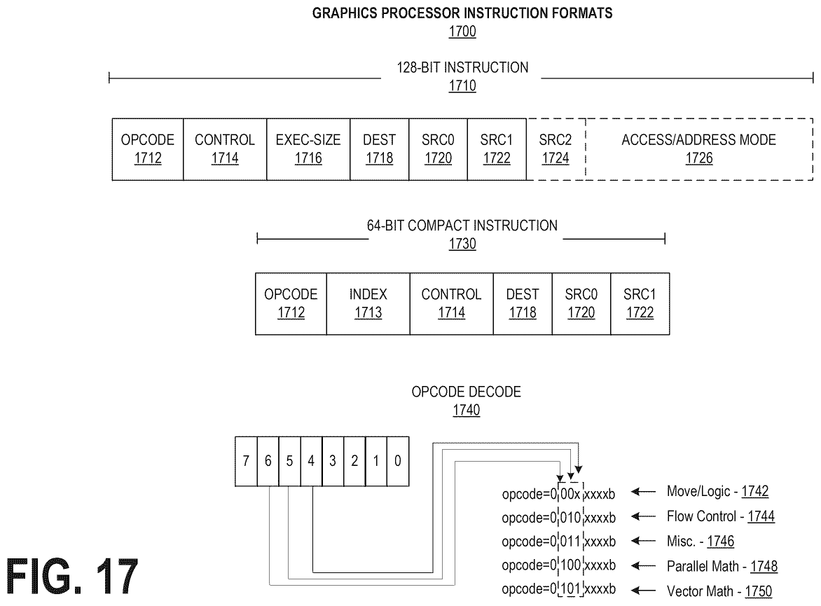

FIG. 17 is a block diagram illustrating a graphics processor instruction formats 1700 according to some examples. In one or more example, the graphics processor execution units support an instruction set having instructions in multiple formats. The solid lined boxes illustrate the components that are generally included in an execution unit instruction, while the dashed lines include components that are optional or that are only included in a sub-set of the instructions. In some examples, instruction format 1700 described and illustrated are macroinstructions, in that they are instructions supplied to the execution unit, as opposed to micro-operations resulting from instruction decode once the instruction is processed.

In some examples, the graphics processor execution units natively support instructions in a 128-bit instruction format 1710. A 64-bit compacted instruction format 1730 is available for some instructions based on the selected instruction, instruction options, and number of operands. The native 128-bit instruction format 1710 provides access to all instruction options, while some options and operations are restricted in the 64-bit compacted format 1730. The native instructions available in the 64-bit compacted format 1730 vary by example. In some examples, the instruction is compacted in part using a set of index values in an index field 1713. The execution unit hardware references a set of compaction tables based on the index values and uses the compaction table outputs to reconstruct a native instruction in the 128-bit instruction format 1710. Other sizes and formats of instruction can be used.

For each format, instruction opcode 1712 defines the operation that the execution unit is to perform. The execution units execute each instruction in parallel across the multiple data elements of each operand. For example, in response to an add instruction the execution unit performs a simultaneous add operation across each color channel representing a texture element or picture element. By default, the execution unit performs each instruction across all data channels of the operands. In some examples, instruction control field 1714 enables control over certain execution options, such as channels selection (e.g., predication) and data channel order (e.g., swizzle). For instructions in the 128-bit instruction format 1710 an exec-size field 1716 limits the number of data channels that will be executed in parallel. In some examples, exec-size field 1716 is not available for use in the 64-bit compact instruction format 1730.

Some execution unit instructions have up to three operands including two source operands, src0 1720, src1 1722, and one destination 1718. In some examples, the execution units support dual destination instructions, where one of the destinations is implied. Data manipulation instructions can have a third source operand (e.g., SRC 2 1724), where the instruction opcode 1712 determines the number of source operands. An instruction's last source operand can be an immediate (e.g., hard-coded) value passed with the instruction.

In some examples, the 128-bit instruction format 1710 includes an access/address mode field 1726 specifying, for example, whether direct register addressing mode or indirect register addressing mode is used. When direct register addressing mode is used, the register address of one or more operands is directly provided by bits in the instruction.

In some examples, the 128-bit instruction format 1710 includes an access/address mode field 1726, which specifies an address mode and/or an access mode for the instruction. In some examples the access mode is used to define a data access alignment for the instruction. Some examples support access modes including a 16-byte aligned access mode and a 1-byte aligned access mode, where the byte alignment of the access mode determines the access alignment of the instruction operands. For example, when in a first mode, the instruction may use byte-aligned addressing for source and destination operands and when in a second mode, the instruction may use 16-byte-aligned addressing for all source and destination operands.

In some examples, the address mode portion of the access/address mode field 1726 determines whether the instruction is to use direct or indirect addressing. When direct register addressing mode is used bits in the instruction directly provide the register address of one or more operands. When indirect register addressing mode is used, the register address of one or more operands may be computed based on an address register value and an address immediate field in the instruction.

In some examples instructions are grouped based on opcode 1712 bit-fields to simplify Opcode decode 1740. For an 8-bitopcode, bits 4, 5, and 6 allow the execution unit to determine the type of opcode. The precise opcode grouping shown is merely an example. In some examples, a move and logic opcode group 1742 includes data movement and logic instructions (e.g., move (mov), compare (cmp)). In some examples, move and logic opcode group 1742 shares the five most significant bits (MSB), where move (mov) instructions are in the form of 0000xxxxb and logic instructions are in the form of 0001xxxxb. A flow control instruction group 1744 (e.g., call, jump (jmp)) includes instructions in the form of 0010xxxxb (e.g., 0x20). A miscellaneous instruction group 1746 includes a mix of instructions, including synchronization instructions (e.g., wait, send) in the form of 0011xxxxb (e.g., 0x 30). A parallel math instruction group 1748 includes component-wise arithmetic instructions (e.g., add, multiply (mul)) in the form of 0100xxxxb (e.g., 0x40). The parallel math instruction group 1748 performs the arithmetic operations in parallel across data channels. The vector math group 1750 includes arithmetic instructions (e.g., dp 4) in the form of 0101xxxxb (e.g., 0x50). The vector math group performs arithmetic such as dot product calculations on vector operands. The illustrated opcode decode 1740, in some examples, can be used to determine which portion of an execution unit will be used to execute a decoded instruction. For example, some instructions may be designated as systolic instructions that will be performed by a systolic array. Other instructions, such as ray-tracing instructions (not shown) can be routed to a ray-tracing core or ray-tracing logic within a slice or partition of execution logic.

### Graphics Pipeline

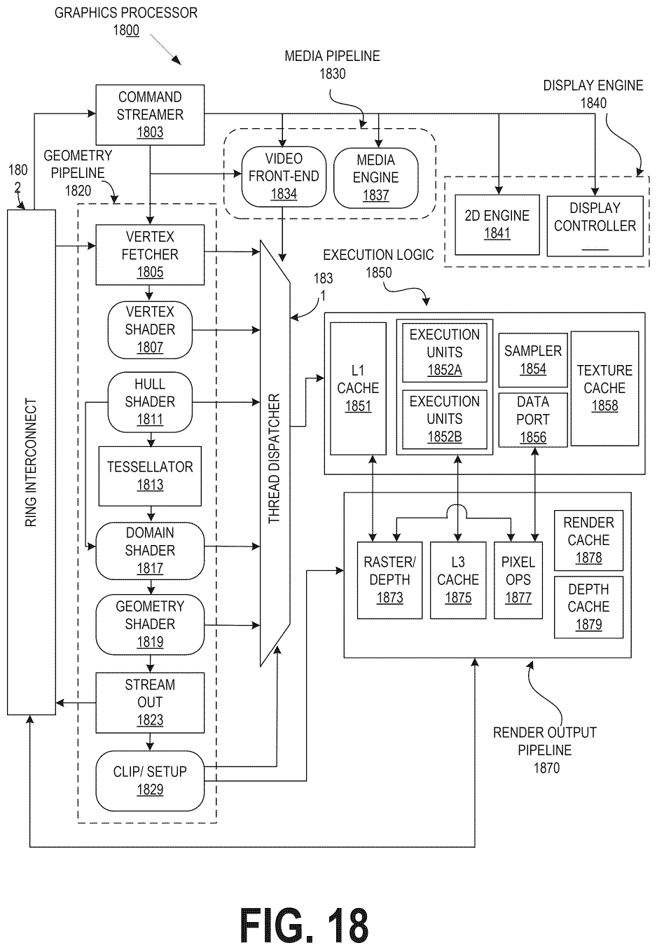

FIG. 18 is a block diagram of another example of a graphics processor 1800. Elements of FIG. 18 having the same reference numbers (or names) as the elements of any other figure herein can operate or function in any manner similar to that described elsewhere herein, but are not limited to such.

In some examples, graphics processor 1800 includes a geometry pipeline 1820, a media pipeline 1830, a display engine 1840, thread execution logic 1850, and a render output pipeline 1870. In some examples, graphics processor 1800 is a graphics processor within a multi-core processing system that includes one or more general-purpose processing cores. The graphics processor is controlled by register writes to one or more control registers (not shown) or via commands issued to graphics processor 1800 via a ring interconnect 1802. In some examples, ring interconnect 1802 couples graphics processor 1800 to other processing components, such as other graphics processors or general-purpose processors. Commands from ring interconnect 1802 are interpreted by a command streamer 1803, which supplies instructions to individual components of the geometry pipeline 1820 or the media pipeline 1830.

In some examples, command streamer 1803 directs the operation of a vertex fetcher 1805 that reads vertex data from memory and executes vertex-processing commands provided by command streamer 1803. In some examples, vertex fetcher 1805 provides vertex data to a vertex shader 1807, which performs coordinate space transformation and lighting operations to each vertex. In some examples, vertex fetcher 1805 and vertex shader 1807 execute vertex-processing instructions by dispatching execution threads to execution units 1852A-1852B via a thread dispatcher 1831.

In some examples, execution units 1852A-1852B are an array of vector processors having an instruction set for performing graphics and media operations. In some examples, execution units 1852A-1852B have an attached L1 cache 1851 that is specific for each array or shared between the arrays. The cache can be configured as a data cache, an instruction cache, or a single cache that is partitioned to contain data and instructions in different partitions.

In some examples, geometry pipeline 1820 includes tessellation components to perform hardware-accelerated tessellation of 3D objects. In some examples, a programmable hull shader 1811 configures the tessellation operations. A programmable domain shader 1817 provides back-end evaluation of tessellation output. A tessellator 1813 operates at the direction of hull shader 1811 and contains special purpose logic to generate a set of detailed geometric objects based on a coarse geometric model that is provided as input to geometry pipeline 1820. In some examples, if tessellation is not used, tessellation components (e.g., hull shader 1811, tessellator 1813, and domain shader 1817) can be bypassed.

In some examples, complete geometric objects can be processed by a geometry shader 1819 via one or more threads dispatched to execution units 1852A-1852B, or can proceed directly to the clipper 1829. In some examples, the geometry shader operates on entire geometric objects, rather than vertices or patches of vertices as in previous stages of the graphics pipeline. If the tessellation is disabled the geometry shader 1819 receives input from the vertex shader 1807. In some examples, geometry shader 1819 is programmable by a geometry shader program to perform geometry tessellation if the tessellation units are disabled.

Before rasterization, a clipper 1829 processes vertex data. The clipper 1829 may be a fixed function clipper or a programmable clipper having clipping and geometry shader functions. In some examples, a rasterizer and depth test component 1873 in the render output pipeline 1870 dispatches pixel shaders to convert the geometric objects into per pixel representations. In some examples, pixel shader logic is included in thread execution logic 1850. In some examples, an application can bypass the rasterizer and depth test component 1873 and access un-rasterized vertex data via a stream out unit 1823.

The graphics processor 1800 has an interconnect bus, interconnect fabric, or some other interconnect mechanism that allows data and message passing amongst the major components of the processor. In some examples, execution units 1852A-1852B and associated logic units (e.g., L1 cache 1851, sampler 1854, texture cache 1858, etc.) interconnect via a data port 1856 to perform memory access and communicate with render output pipeline components of the processor. In some examples, sampler 1854, caches 1851, 1858 and execution units 1852A-1852B each have separate memory access paths. In some examples the texture cache 1858 can also be configured as a sampler cache.

In some examples, render output pipeline 1870 contains a rasterizer and depth test component 1873 that converts vertex-based objects into an associated pixel-based representation. In some examples, the rasterizer logic includes a windower/masker unit to perform fixed function triangle and line rasterization. An associated render cache 1878 and depth cache 1879 are also available in some examples. A pixel operations component 1877 performs pixel-based operations on the data, though in some instances, pixel operations associated with 2D operations (e.g. bit block image transfers with blending) are performed by the 2D engine 1841, or substituted at display time by the display controller 1843 using overlay display planes. In some examples, a shared L3 cache 1875 is available to all graphics components, allowing the sharing of data without the use of main system memory.

In some examples, media pipeline 1830 includes a media engine 1837 and a video front-end 1834. In some examples, video front-end 1834 receives pipeline commands from the command streamer 1803. In some examples, media pipeline 1830 includes a separate command streamer. In some examples, video front-end 1834 processes media commands before sending the command to the media engine 1837. In some examples, media engine 1837 includes thread spawning functionality to spawn threads for dispatch to thread execution logic 1850 via thread dispatcher 1831.

In some examples, graphics processor 1800 includes a display engine 1840. In some examples, display engine 1840 is external to graphics processor 1800 and couples with the graphics processor via the ring interconnect 1802, or some other interconnect bus or fabric. In some examples, display engine 1840 includes a 2D engine 1841 and a display controller 1843. In some examples, display engine 1840 contains special purpose logic capable of operating independently of the 3D pipeline. In some examples, display controller 1843 couples with a display device (not shown), which may be a system integrated display device, as in a laptop computer, or an external display device attached via a display device connector.

In some examples, the geometry pipeline 1820 and media pipeline 1830 are configurable to perform operations based on multiple graphics and media programming interfaces and are not specific to any one application programming interface (API). In some examples, driver software for the graphics processor translates API calls that are specific to a particular graphics or media library into commands that can be processed by the graphics processor. In some examples, support is provided for the Open Graphics Library (OpenGL), Open Computing Language (OpenCL), and/or Vulkan graphics and compute API, all from the Khronos Group. In some examples, support may also be provided for the Direct3D library from the Microsoft Corporation. In some examples, a combination of these libraries may be supported. Support may also be provided for the Open Source Computer Vision Library (OpenCV). A future API with a compatible 3D pipeline would also be supported if a mapping can be made from the pipeline of the future API to the pipeline of the graphics processor.

### Graphics Pipeline Programming

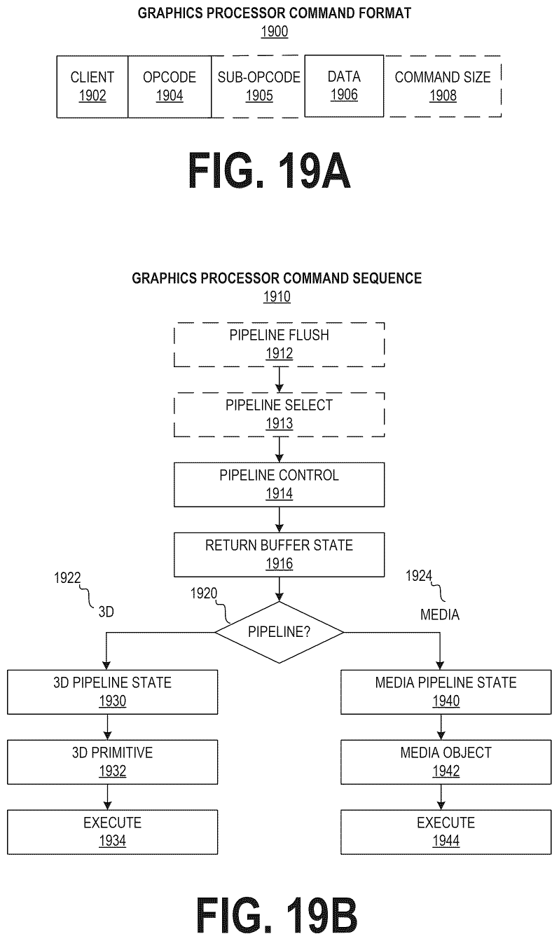

FIG. 19A is a block diagram illustrating a graphics processor command format 1900 according to some examples. FIG. 19B is a block diagram illustrating a graphics processor command sequence 1910 according to an example. The solid lined boxes in FIG. 19A illustrate the components that are generally included in a graphics command while the dashed lines include components that are optional or that are only included in a sub-set of the graphics commands. The graphics processor command format 1900 of FIG. 19A includes data fields to identify a client 1902, a command operation code (opcode) 1904, and data 1906 for the command. A sub-opcode 1905 and a command size 1908 are also included in some commands.

In some examples, client 1902 specifies the client unit of the graphics device that processes the command data. In some examples, a graphics processor command parser examines the client field of each command to condition the further processing of the command and route the command data to the appropriate client unit. In some examples, the graphics processor client units include a memory interface unit, a render unit, a 2D unit, a 3D unit, and a media unit. Each client unit has a corresponding processing pipeline that processes the commands. Once the command is received by the client unit, the client unit reads the opcode 1904 and, if present, sub-opcode 1905 to determine the operation to perform. The client unit performs the command using information in data field 1906. For some commands an explicit command size 1908 is expected to specify the size of the command. In some examples, the command parser automatically determines the size of at least some of the commands based on the command opcode. In some examples commands are aligned via multiples of a double word. Other command formats can be used.

The flow diagram in FIG. 19B illustrates a graphics processor command sequence 1910. In some examples, software or firmware of a data processing system that features an example of a graphics processor uses a version of the command sequence shown to set up, execute, and terminate a set of graphics operations. A sample command sequence is shown and described for purposes of example only as examples are not limited to these specific commands or to this command sequence. Moreover, the commands may be issued as batch of commands in a command sequence, such that the graphics processor will process the sequence of commands in at least partially concurrence.

In some examples, the graphics processor command sequence 1910 may begin with a pipeline flush command 1912 to cause any active graphics pipeline to complete the currently pending commands for the pipeline. In some examples, the 3D pipeline 1922 and the media pipeline 1924 do not operate concurrently. The pipeline flush is performed to cause the active graphics pipeline to complete any pending commands. In response to a pipeline flush, the command parser for the graphics processor will pause command processing until the active drawing engines complete pending operations and the relevant read caches are invalidated. Optionally, any data in the render cache that is marked ‘dirty’ can be flushed to memory. In some examples, pipeline flush command 1912 can be used for pipeline synchronization or before placing the graphics processor into a low power state.

In some examples, a pipeline select command 1913 is used when a command sequence requires the graphics processor to explicitly switch between pipelines. In some examples, a pipeline select command 1913 is required only once within an execution context before issuing pipeline commands unless the context is to issue commands for both pipelines. In some examples, a pipeline flush command 1912 is required immediately before a pipeline switch via the pipeline select command 1913.

In some examples, a pipeline control command 1914 configures a graphics pipeline for operation and is used to program the 3D pipeline 1922 and the media pipeline 1924. In some examples, pipeline control command 1914 configures the pipeline state for the active pipeline. In some examples, the pipeline control command 1914 is used for pipeline synchronization and to clear data from one or more cache memories within the active pipeline before processing a batch of commands.

In some examples, return buffer state commands 1916 are used to configure a set of return buffers for the respective pipelines to write data. Some pipeline operations require the allocation, selection, or configuration of one or more return buffers into which the operations write intermediate data during processing. In some examples, the graphics processor also uses one or more return buffers to store output data and to perform cross thread communication. In some examples, the return buffer state includes selecting the size and number of return buffers to use for a set of pipeline operations.

The remaining commands in the command sequence differ based on the active pipeline for operations. Based on a pipeline determination 1920, the command sequence is tailored to the 3D pipeline 1922 beginning with the 3D pipeline state 1930 or the media pipeline 1924 beginning at the media pipeline state 1940.

The commands to configure the 3D pipeline state 1930 include 3D state setting commands for vertex buffer state, vertex element state, constant color state, depth buffer state, and other state variables that are to be configured before 3D primitive commands are processed. The values of these commands are determined at least in part based on the particular 3D API in use. In some examples, 3D pipeline state 1930 commands are also able to selectively disable or bypass certain pipeline elements if those elements will not be used.

In some examples, 3D primitive 1932 command is used to submit 3D primitives to be processed by the 3D pipeline. Commands and associated parameters that are passed to the graphics processor via the 3D primitive 1932 command are forwarded to the vertex fetch function in the graphics pipeline. The vertex fetch function uses the 3D primitive 1932 command data to generate vertex data structures. The vertex data structures are stored in one or more return buffers. In some examples, 3D primitive 1932 command is used to perform vertex operations on 3D primitives via vertex shaders. To process vertex shaders, 3D pipeline 1922 dispatches shader execution threads to graphics processor execution units.

In some examples, 3D pipeline 1922 is triggered via an execute 1934 command or event. In some examples, a register write triggers command execution. In some examples execution is triggered via a ‘go’ or ‘kick’ command in the command sequence. In some examples, command execution is triggered using a pipeline synchronization command to flush the command sequence through the graphics pipeline. The 3D pipeline will perform geometry processing for the 3D primitives. Once operations are complete, the resulting geometric objects are rasterized and the pixel engine colors the resulting pixels. Additional commands to control pixel shading and pixel back end operations may also be included for those operations.

In some examples, the graphics processor command sequence 1910 follows the media pipeline 1924 path when performing media operations. In general, the specific use and manner of programming for the media pipeline 1924 depends on the media or compute operations to be performed. Specific media decode operations may be offloaded to the media pipeline during media decode. In some examples, the media pipeline can also be bypassed and media decode can be performed in whole or in part using resources provided by one or more general-purpose processing cores. In some examples, the media pipeline also includes elements for general-purpose graphics processor unit (GPGPU) operations, where the graphics processor is used to perform SIMD vector operations using computational shader programs that are not explicitly related to the rendering of graphics primitives.

In some examples, media pipeline 1924 is configured in a similar manner as the 3D pipeline 1922. A set of commands to configure the media pipeline state 1940 are dispatched or placed into a command queue before the media object commands 1942. In some examples, commands for the media pipeline state 1940 include data to configure the media pipeline elements that will be used to process the media objects. This includes data to configure the video decode and video encode logic within the media pipeline, such as encode or decode format. In some examples, commands for the media pipeline state 1940 also support the use of one or more pointers to “indirect” state elements that contain a batch of state settings.

In some examples, media object commands 1942 supply pointers to media objects for processing by the media pipeline. The media objects include memory buffers containing video data to be processed. In some examples, all media pipeline states must be valid before issuing a media object command 1942. Once the pipeline state is configured and media object commands 1942 are queued, the media pipeline 1924 is triggered via an execute command 1944 or an equivalent execute event (e.g., register write). Output from media pipeline 1924 may then be post processed by operations provided by the 3D pipeline 1922 or the media pipeline 1924. In some examples, GPGPU operations are configured and executed in a similar manner as media operations.

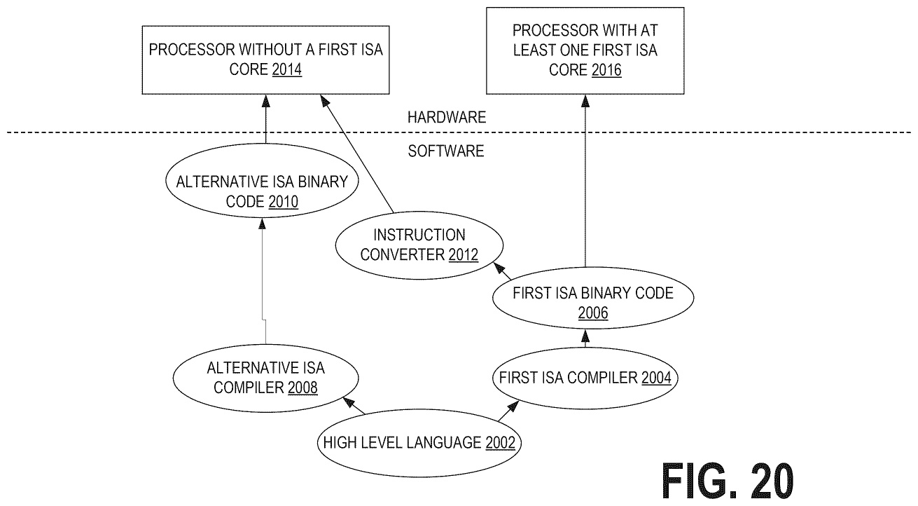

FIG. 20 is a block diagram illustrating the use of a software instruction converter to convert binary instructions in a source ISA to binary instructions in a target ISA according to examples. In the illustrated example, the instruction converter is a software instruction converter, although alternatively the instruction converter may be implemented in software, firmware, hardware, or various combinations thereof. FIG. 20 shows a program in a high-level language 2002 may be compiled using a first ISA compiler 2004 to generate first ISA binary code 2006 that may be natively executed by a processor with at least one first ISA core 2016. The processor with at least one first ISA core 2016 represents any processor that can perform substantially the same functions as an Intel® processor with at least one first ISA core by compatibly executing or otherwise processing (1) a substantial portion of the first ISA or (2) object code versions of applications or other software targeted to run on an Intel processor with at least one first ISA core, in order to achieve substantially the same result as a processor with at least one first ISA core. The first ISA compiler 2004 represents a compiler that is operable to generate first ISA binary code 2006 (e.g., object code) that can, with or without additional linkage processing, be executed on the processor with at least one first ISA core 2016. Similarly, FIG. 20 shows the program in the high-level language 2002 may be compiled using an alternative ISA compiler 2008 to generate alternative ISA binary code 2010 that may be natively executed by a processor without a first ISA core 2014. The instruction converter 2012 is used to convert the first ISA binary code 2006 into code that may be natively executed by the processor without a first ISA core 2014. This converted code is not necessarily to be the same as the alternative ISA binary code 2010; however, the converted code will accomplish the general operation and be made up of instructions from the alternative ISA. Thus, the instruction converter 2012 represents software, firmware, hardware, or a combination thereof that, through emulation, simulation or any other process, allows a processor or other electronic device that does not have a first ISA processor or core to execute the first ISA binary code 2006.

### IP Core Implementations

One or more aspects of at least some examples may be implemented by representative code stored on a machine-readable medium which represents and/or defines logic within an integrated circuit such as a processor. For example, the machine-readable medium may include instructions which represent various logic within the processor. When read by a machine, the instructions may cause the machine to fabricate the logic to perform the techniques described herein. Such representations, known as “IP cores,” are reusable units of logic for an integrated circuit that may be stored on a tangible, machine-readable medium as a hardware model that describes the structure of the integrated circuit. The hardware model may be supplied to various customers or manufacturing facilities, which load the hardware model on fabrication machines that manufacture the integrated circuit. The integrated circuit may be fabricated such that the circuit performs operations described in association with any of the examples described herein.

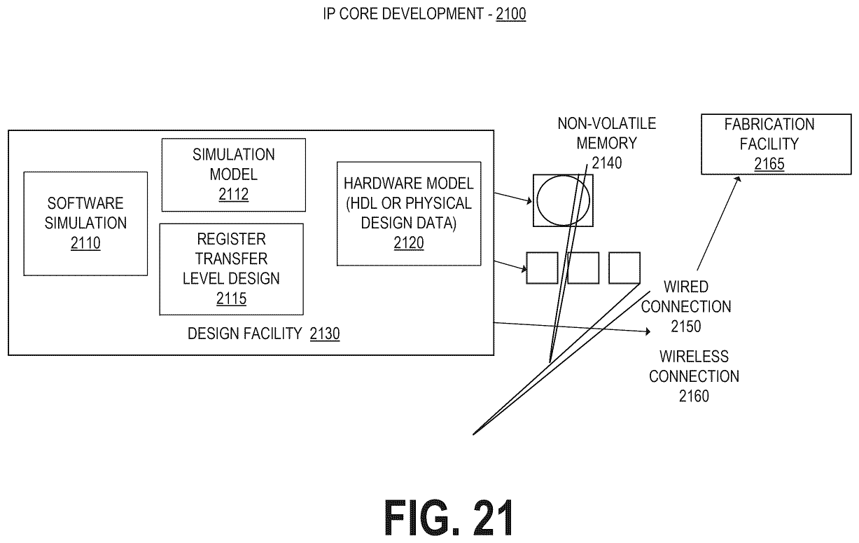

FIG. 21 is a block diagram illustrating an IP core development system 2100 that may be used to manufacture an integrated circuit to perform operations according to some examples. The IP core development system 2100 may be used to generate modular, re-usable designs that can be incorporated into a larger design or used to construct an entire integrated circuit (e.g., an SOC integrated circuit). A design facility 2130 can generate a software simulation 2110 of an IP core design in a high-level programming language (e.g., C/C++). The software simulation 2110 can be used to design, test, and verify the behavior of the IP core using a simulation model 2112. The simulation model 2112 may include functional, behavioral, and/or timing simulations. A register transfer level (RTL) design 2115 can then be created or synthesized from the simulation model 2112. The RTL design 2115 is an abstraction of the behavior of the integrated circuit that models the flow of digital signals between hardware registers, including the associated logic performed using the modeled digital signals. In addition to an RTL design 2115, lower-level designs at the logic level or transistor level may also be created, designed, or synthesized. Thus, the particular details of the initial design and simulation may vary.

The RTL design 2115 or equivalent may be further synthesized by the design facility into a hardware model 2120, which may be in a hardware description language (HDL), or some other representation of physical design data. The HDL may be further simulated or tested to verify the IP core design. The IP core design can be stored for delivery to a fabrication facility 2165 using non-volatile memory 2140 (e.g., hard disk, flash memory, or any non-volatile storage medium). Alternatively, the IP core design may be transmitted (e.g., via the Internet) over a wired connection 2150 or wireless connection 2160. The fabrication facility 2165 may then fabricate an integrated circuit that is based at least in part on the IP core design. The fabricated integrated circuit can be configured to perform operations in accordance with at least some examples described herein.

### EXAMPLES

Illustrative examples of the technologies disclosed herein are provided below. An embodiment of the technologies may include any one or more, and any compatible combination of, the examples described below.

Example 1 is an apparatus that includes a configurable micro-architectural (uarch) circuit. It also includes one or more comparator circuits to generate a configuration state signal based on an operating point indicator associated with the configurable uarch circuit. It further includes an interface circuit coupled to the one or more comparator circuits and to the configurable uarch circuit to control a configuration of the configurable uarch circuit based on the configuration state signal.

Example 2 includes the subject matter of example 1, and wherein the configurable uarch circuit is a speculative execution circuit with a configurable amount of speculation that is controlled by the interface circuit.

Example 3 includes the subject matter of any of examples 1-2, and wherein the configurable uarch circuit is a pulse-glide circuit with a configurable number of queue execution time slots that is controlled by the interface circuit.

Example 4 includes the subject matter of any of examples 1-3, and wherein the configurable uarch circuit is a part of a processor partition that includes multiple configurable uarch circuits.

Example 5 includes the subject matter of any of examples 1-4, and wherein the multiple configurable uarch circuits are coupled to the interface circuit to be configured based on the configuration state signal.

Example 6 includes the subject matter of any of examples 1-5, and wherein the interface circuit includes a decoder circuit and a finite state machine circuit to control the configuration of the configurable uarch circuit.

Example 7 includes the subject matter of any of examples 1-6, and wherein the operating point indicator includes a clock frequency or a clock frequency ratio value.

Example 8 includes the subject matter of any of examples 1-7, and comprising a multiplexer circuit coupled between the one or more comparator circuits and the interface circuit to provide a selected one of the configuration state signal and a disabled mode signal.

Example 9 includes the subject matter of any of examples 1-8, and wherein the configuration state signal includes a plurality of signal lines.

Example 10 includes the subject matter of any of examples 1-9, and comprising a uarch configuration control circuit to provide uarch P-state threshold values to the one or more comparator circuits.

Example 11 includes the subject matter of any of examples 1-10, and wherein the uarch configuration control circuit includes at least one table to define different configurations for the configurable uarch circuit based on the operating point indicator.

Example 12 includes the subject matter of any of examples 1-11, and wherein the table includes configuration mode definitions for a plurality of configurable uarch circuits.

Example 13 is a processor apparatus that includes a processing core that includes a plurality of configurable micro-architectural (uarch) circuits. It also includes comparator circuits to generate a configuration state signal based on an operating point indicator associated with the processing core. It further includes at least one interface circuit coupled to the comparator circuits and to the configurable uarch circuits to control configurations of the configurable uarch circuits based on the configuration state signal. The apparatus also includes a control circuit to provide operating point indicator threshold levels for the comparator circuits.

Example 14 includes the subject matter of example 13, and wherein the configurable uarch circuits include a speculative execution circuit with a configurable amount of speculation that is controlled by the at least one interface circuit.

Example 15 includes the subject matter of any of examples 13-14, and wherein the configurable uarch circuits include a pulse-glide circuit with a configurable number of queue execution time slots that is controlled by the interface circuit.

Example 16 includes the subject matter of any of examples 13-15, and wherein the at least one interface circuit includes a decoder circuit to control the configurations of the configurable uarch circuits.

Example 17 includes the subject matter of any of examples 13-16, and wherein the operating point indicator includes a clock frequency or a clock frequency ratio value for the processing core.

Example 18 includes the subject matter of any of examples 13-17, and wherein the control circuit is part of a system management controller circuit external to the processing core.

Example 19 includes the subject matter of any of examples 13-18, and comprising a controller circuit to program the comparator circuits based on values received from the control circuit in the system management controller circuit.

Example 20 includes the subject matter of any of examples 13-19, and wherein the controller circuit includes at least one table to define different configurations for the configurable uarch circuits based on the operating point indicator.

Example 21 is a processor package apparatus that includes at least one processor die and at least one IO die. The at least one processor die includes a configurable micro-architectural (uarch) circuit, one or more comparator circuits to generate a configuration state signal based on an operating point indicator associated with the configurable uarch circuit, and an interface circuit coupled to the one or more comparator circuits and to the configurable uarch circuit to control a configuration of the configurable uarch circuit based on the configuration state signal. The at least one input/output (IO) die is coupled to the at least one processor die to provide it with a communication link with a device external to the processor package apparatus.

Example 22 includes the subject matter of example 21, and wherein the configurable uarch circuit is a speculative execution circuit with a configurable amount of speculation that is controlled by the interface circuit.

Example 23 includes the subject matter of any of examples 21-22, and wherein the configurable uarch circuit is a pulse-glide circuit with a configurable number of queue execution time slots that is controlled by the interface circuit.

Example 24 includes the subject matter of any of examples 21-23, and wherein the configurable uarch circuit is a part of a processor partition that includes multiple configurable uarch circuits.

Example 25 includes the subject matter of any of examples 21-24, and wherein the multiple configurable uarch circuits are coupled to the interface circuit to be configured based on the configuration state signal.

Example 26 includes the subject matter of any of examples 21-25, and wherein the interface circuit includes a decoder circuit and a finite state machine circuit to control the configuration of the configurable uarch circuit.

Example 27 includes the subject matter of any of examples 21-26, and wherein the operating point indicator includes a clock frequency or a clock frequency ratio value.

Example 28 includes the subject matter of any of examples 21-27, and comprising a multiplexer circuit coupled between the one or more comparator circuits and the interface circuit to provide a selected one of the configuration state signal and a disabled mode signal.

Example 29 includes the subject matter of any of examples 21-28, and wherein the configuration state signal includes a plurality of signal lines.

Example 30 includes the subject matter of any of examples 21-29, and comprising a uarch configuration control circuit to provide uarch P-state threshold values to the one or more comparator circuits.

Example 31 includes the subject matter of any of examples 21-30, and wherein the uarch configuration control circuit includes at least one table to define different configurations for the configurable uarch circuit based on the operating point indicator.

Example 32 includes the subject matter of any of examples 21-31, and wherein the table includes configuration mode definitions for a plurality of configurable uarch circuits.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

Program code may be applied to input information to perform the functions described herein and generate output information. The output information may be applied to one or more output devices, in known fashion. For purposes of this application, a processing system includes any system that has a processor, such as, for example, a digital signal processor (DSP), a microcontroller, an application specific integrated circuit (ASIC), a field programmable gate array (FPGA), a microprocessor, or any combination thereof.

The program code may be implemented in a high-level procedural or object-oriented programming language to communicate with a processing system. The program code may also be implemented in assembly or machine language, if desired. In fact, the mechanisms described herein are not limited in scope to any particular programming language. In any case, the language may be a compiled or interpreted language.

Examples of the mechanisms disclosed herein may be implemented in hardware, software, firmware, or a combination of such implementation approaches. Examples may be implemented as computer programs or program code executing on programmable systems comprising at least one processor, a storage system (including volatile and non-volatile memory and/or storage elements), at least one input device, and at least one output device.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, examples also include non-transitory, tangible machine-readable media containing instructions or containing design data, such as Hardware Description Language (HDL), which defines structures, circuits, apparatuses, processors and/or system features described herein. Such examples may also be referred to as program products.

In some cases, an instruction converter may be used to convert an instruction from a source instruction set architecture to a target instruction set architecture. For example, the instruction converter may translate (e.g., using static binary translation, dynamic binary translation including dynamic compilation), morph, emulate, or otherwise convert an instruction to one or more other instructions to be processed by the core. The instruction converter may be implemented in software, hardware, firmware, or a combination thereof. The instruction converter may be on processor, off processor, or part on and part off processor.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a configurable micro-architectural (uarch) circuit;
one or more comparator circuits to generate a configuration state signal based on an operating point indicator associated with the configurable uarch circuit; and
an interface circuit coupled to the one or more comparator circuits and to the configurable uarch circuit to control a configuration of the configurable uarch circuit based on the configuration state signal.

2. The apparatus of claim 1, wherein the configurable uarch circuit is a speculative execution circuit with a configurable amount of speculation that is controlled by the interface circuit.

3. The apparatus of claim 1, wherein the configurable uarch circuit is a pulse-glide circuit with a configurable number of queue execution time slots that are controlled by the interface circuit.

4. The apparatus of claim 1, wherein the configurable uarch circuit is a part of a processor partition that includes multiple configurable uarch circuits.

5. The apparatus of claim 4, wherein the multiple configurable uarch circuits are coupled to the interface circuit to be configured based on the configuration state signal.

6. The apparatus of claim 1, wherein the interface circuit includes a decoder circuit and a finite state machine circuit to control the configuration of the configurable uarch circuit.

7. The apparatus of claim 1, wherein the operating point indicator includes a clock frequency or a clock frequency ratio value.

8. The apparatus of claim 1, wherein the configuration state signal includes a plurality of signal lines.

9. The apparatus of claim 1, comprising a uarch configuration control circuit to provide uarch P-state threshold values to the one or more comparator circuits.

10. The apparatus of claim 9, wherein the uarch configuration control circuit includes at least one table to define different configurations for the configurable uarch circuit based on the operating point indicator.

11. A processor apparatus, comprising:
a plurality of configurable micro-architectural (uarch) circuits;
comparator circuits to generate a configuration state signal based on an operating point indicator associated with a processing core including the configurable uarch circuits;
at least one interface circuit coupled to the comparator circuits and to the configurable uarch circuits to control configurations of the configurable uarch circuits based on the configuration state signal; and
a control circuit to provide operating point indicator threshold levels for the comparator circuits.

12. The apparatus of claim 11, wherein the configurable uarch circuits include a speculative execution circuit with a configurable amount of speculation that is controlled by the at least one interface circuit.

13. The apparatus of claim 12, wherein the configurable uarch circuits include a pulse-glide circuit with a configurable number of queue execution time slots that is controlled by the interface circuit.

14. The apparatus of claim 11, wherein the at least one interface circuit includes a decoder circuit to control the configurations of the configurable uarch circuits.

15. The apparatus of claim 11, wherein the operating point indicator includes a clock frequency or a clock frequency ratio value for the processing core.

16. The apparatus of claim 11, wherein the control circuit is part of a system management controller circuit external to the processing core.

17. The apparatus of claim 16, comprising a controller circuit to program the comparator circuits based on values received from the control circuit in the system management controller circuit.

18. The apparatus of claim 17, wherein the controller circuit includes at least one table to define different configurations for the configurable uarch circuits based on the operating point indicator.

19. A processor package apparatus, comprising:
at least one processor die including:
a configurable micro-architectural (uarch) circuit;
one or more comparator circuits to generate a configuration state signal based on an operating point indicator associated with the configurable uarch circuit; and
an interface circuit coupled to the one or more comparator circuits and to the configurable uarch circuit to control a configuration of the configurable uarch circuit based on the configuration state signal; and
at least one input/output (IO) die coupled to the at least one processor die to provide it with a communication link with a device external to the processor package apparatus.

20. The apparatus of claim 19, wherein the configurable uarch circuit is a speculative execution circuit with a configurable amount of speculation that is controlled by the interface circuit.
